(19) United States
(12) Patent Application Publication
(10) Pub. No.: US 2025/0090963 A1
(43) Pub. Date: Mar. 20, 2025

(54) EFFICIENT PACKET-LOSS PROTECTED DATA ENCODING AND/OR DECODING

(71) Applicant: QUALCOMM Incorporated, San Diego, CA (US)

(72) Inventors: Zisis Iason SKORDILIS, San Diego, CA (US); Vivek RAJENDRAN, San Diego, CA (US); Guillaume Konrad SAUTIERE, Amsterdam (NL); Duminda DEWASURENDRA, San Diego, CA (US); Daniel Jared SINDER, San Diego, CA (US)

(21) Appl. No.: 18/294,490

(22) PCT Filed: Sep. 8, 2022
(86) PCT No.: PCT/US22/76082

§ 371 Date: Feb. 1, 2024

(30) Foreign Application Priority Data
Sep. 27, 2021 (GR) 20210100637

(51) Int. Cl. A63F 13/77; A63F 13/35

(52) U.S. Cl. CPC A63F 13/77; A63F 13/35

(57) ABSTRACT

A device includes a memory and one or more processors coupled to the memory and configured to execute instructions from the memory. Execution of the instructions causes the one or more processors to combine two or more data portions to generate input data for a decoder network. A first data portion of the two or more data portions is based on a first encoding of a data sample by a multiple description coding network and content of a second data portion of the two or more data portions depends on whether data based on a second encoding of the data sample by the multiple description coding network is available. Execution of the instructions also causes the one or more processors to obtain, from the decoder network, output data based on the input data and to generate a representation of the data sample based on the output data.

### I. CROSS-REFERENCE TO RELATED APPLICATIONS

The present application claims the benefit of priority from the commonly owned Greece Provisional Patent Application No. 20/210,100637, filed Sep. 27, 2021, the contents of which are expressly incorporated herein by reference in their entirety.

### II. FIELD

The present disclosure is generally related to encoding and/or decoding data.

### III. DESCRIPTION OF RELATED ART

Advances in technology have resulted in smaller and more powerful computing devices. For example, there currently exist a variety of portable personal computing devices, including wireless telephones such as mobile and smart phones, tablets and laptop computers that are small, lightweight, and easily carried by users. These devices can communicate voice packets, data packets, or both, over wired or wireless networks. Further, many such devices incorporate additional functionality such as a digital still camera, a digital video camera, a digital recorder, and an audio file player. Also, such devices can process executable instructions, including software applications, such as a web browser application, that can be used to access the Internet. As such, these devices can include significant computing capabilities.

Many communication channels used for voice and/or data communications are lossy. To illustrate, when a first device sends packets to a second device over a wireless network, some of the packets can be lost (e.g., not received by the second device). Further, some of the packets may be delayed sufficiently that the second device treats them as lost even though they are eventually received. In both of these situations, the lost or delayed packets can result in reduced quality of the user experience, such as lower quality audio and/or video output (as compared to the audio and/or video quality of the data originally sent by the first device).

Various strategies have been used to mitigate the impact of such losses. Many of these strategies entail transmission of additional data between the first device and the second device in an attempt to make up for lost or delayed data. For example, if the second device fails to receive a particular packet within some expected timeframe, the second device may ask the first device to retransmit the particular packet. In this example, in addition to the original data, the communications between the first device and the second device include a retransmission request and retransmitted data.

As another example, so called “forward error correction” can be used. In forward error correction schemes, redundant data is added to the packets sent from the first device to the second device with the intent that if a packet is lost, redundant data in another packet can be used to mitigate effects of the lost packet. As one simple illustration, in a fully redundant forward error correction scheme, the first device sends two copies of every packet that it sends to the second device. In such as scheme, if temporary channel conditions prevent the second device from receiving a first copy of the packet, the second device may still receive the second copy of the packet and thereby have access to the entire set of data transmitted by the first device. Thus, in this simple example, the impact of transmission losses can be significantly reduced, but at the cost of using bandwidth and power to transmit a large amount of data that will never be used because the second device only needs one of the copies of the packet.

### IV. SUMMARY

According to a particular aspect, a device includes a memory, and one or more processors coupled to the memory and configured to execute instructions from the memory. Execution of the instructions causes the one or more processors to combine two or more data portions to generate input data for a decoder network. A first data portion of the two or more data portions is based on a first encoding of a data sample by a multiple description coding network, and content of a second data portion of the two or more data portions depends on whether data based on a second encoding of the data sample by the multiple description coding network is available. Execution of the instructions also causes the one or more processors to obtain, from the decoder network, output data based on the input data, and to generate a representation of the data sample based on the output data.

According to another particular aspect, a method includes combining two or more data portions to generate input data for a decoder network. A first data portion of the two or more data portions is based on a first encoding of a data sample by a multiple description coding network, and content of a second data portion of the two or more data portions depends on whether a second encoding of the data sample by the multiple description coding network is available. The method also includes obtaining, from the decoder network, output data based on the input data, and generating a representation of the data sample based on the output data.

According to another particular aspect, an apparatus includes means for combining two or more data portions to generate input data for a decoder network. A first data portion of the two or more data portions is based on a first encoding of a data sample by a multiple description coding network, and content of a second data portion of the two or more data portions depends on whether a second encoding of the data sample by the multiple description coding network is available. The apparatus also includes means for obtaining, from the decoder network, output data based on the input data, and means for generating a representation of the data sample based on the output data.

According to another particular aspect, a non-transitory computer-readable medium stores instructions executable by one or more processors to combine two or more data portions to generate input data for a decoder network. A first data portion of the two or more data portions is based on a first encoding of a data sample by a multiple description coding network, and content of a second data portion of the two or more data portions depends on whether data based on a second encoding of the data sample by the multiple description coding network is available. Execution of the instructions also causes the one or more processors to obtain, from the decoder network, output data based on the input data, and to generate a representation of the data sample based on the output data.

According to another particular aspect, a device includes a memory, and one or more processors coupled to the memory and configured to execute instructions from the memory. Execution of the instructions causes the one or more processors to obtain an encoded data output corresponding to a data sample processed by a multiple description coding encoder network. The encoded data output include a first encoding of the data sample and a second encoding of the data sample that is distinct from, and at least partially redundant to, the first encoding. Execution of the instructions also causes the one or more processors to initiate transmission of a first data packet via a transmission medium. The first data packet includes data representing the first encoding. Execution of the instructions also causes the one or more processors to initiate transmission of a second data packet via the transmission medium. The second data packet includes data representing the second encoding.

According to another particular aspect, a method includes obtaining an encoded data output corresponding to a data sample processed by a multiple description coding encoder network. The encoded data output includes a first encoding of the data sample and a second encoding of the data sample that is distinct from, and at least partially redundant to, the first encoding. The method also includes causing a first data packet including data representing the first encoding to be sent via a transmission medium. The method also includes causing a second data packet including data representing the second encoding to be sent via the transmission medium.

According to another particular aspect, an apparatus includes means for obtaining an encoded data output corresponding to a data sample processed by a multiple description coding encoder network. The encoded data output includes a first encoding of the data sample and a second encoding of the data sample that is distinct from, and at least partially redundant to, the first encoding. The apparatus also includes means for initiating transmission of a first data packet via a transmission medium. The first data packet includes data representing the first encoding. The apparatus further includes means for initiating transmission of a second data packet via the transmission medium. The second data packet includes data representing the second encoding.

According to another particular aspect, a computer-readable storage device stores instructions executable by one or more processors to obtain an encoded data output corresponding to a data sample processed by a multiple description coding encoder network. The encoded data output includes a first encoding of the data sample and a second encoding of the data sample that is distinct from, and at least partially redundant to, the first encoding. Execution of the instructions also causes the one or more processors to initiate transmission of a first data packet via a transmission medium. The first data packet includes data representing the first encoding. Execution of the instructions also causes the one or more processors to initiate transmission of a second data packet via the transmission medium. The second data packet includes data representing the second encoding.

### V. BRIEF DESCRIPTION OF THE DRAWINGS

FIG. 1 is a diagram of a particular illustrative example of a system including two or more devices configured to communicate via transmission of encoded data.

FIGS. 2A, 2B, 2C, and 2D are diagrams of examples of operation of the system of FIG. 1.

FIGS. 3A, 3B, and 3C are diagrams of particular examples of aspects of operation of an encoding device of the system of FIG. 1.

FIGS. 4A, 4B, and 4C are diagrams of particular examples of additional aspects of operation of an encoding device of the system of FIG. 1.

FIG. 5A is a diagram of a particular example of further aspects of training an encoding device of the system of FIG. 1.

FIG. 5B is a diagram of a particular example of further aspects of operation of an encoding device of the system of FIG. 1.

FIGS. 5C, 5D, 5E, and 5F are diagrams of examples of aspects of operation of a decoding device of the system of FIG. 1.

FIG. 6A is a diagram of a particular example of additional aspects of operation of an encoding device of the system of FIG. 1.

FIG. 6B is a diagram of a particular example of additional aspects of operation of a decoding device of the system of FIG. 1.

FIGS. 7A and 7B are diagrams of particular examples of further aspects of operation of a decoding device of the system of FIG. 1.

FIG. 8 is a flowchart of a particular example of a method of operation of an encoding device of the system of FIG. 1.

FIG. 9 is a flowchart of another particular example of a method of operation of an encoding device of the system of FIG. 1.

FIG. 10 is a flowchart of a particular example of a method of operation of a decoding device of the system of FIG. 1.

FIG. 11 is a flowchart of another particular example of a method of operation of a decoding device of the system of FIG. 1.

FIG. 12 is a diagram of a particular example of components of an encoding device of FIG. 1 in an integrated circuit.

FIG. 13 is a diagram of a particular example of components of a decoding device of FIG. 1 in an integrated circuit.

FIG. 14 is a block diagram of a particular illustrative example of a device that is operable to perform encoding, decoding, or both.

### VI. DETAILED DESCRIPTION

As explained above, transmission channels are lossy. Packets sent through the channel can be lost or delayed sufficiently to be too late to be useful. For example, streaming data, such as streaming audio data and/or streaming video data, is often encoded and decoded in time-windowed segments, such as frames. If a packet is delayed sufficiently that it is not available when it is needed to decode a particular frame, the packet is effectively lost, even if it is later received. Loss of packets in the channel (also called Frame Erasures (FE)) causes degradation in the quality of the decoded data stream.

Aspects disclosed herein enable efficient (e.g., in terms of bandwidth utilization and power) communication in a manner that is resilient to packet losses. For example, quality degradation due to frame erasures is reduced without using significant bandwidth for communication of error correction data. Additionally, the aspects disclosed herein can be used for voice communications, video communications, or other data communications (such as communication of game data), or combinations thereof (e.g., multimedia communications).

According to a particular aspect, a multiple description coder (MDC) network is used to encode data for transmission. The MDC network is a machine learning-based network that is trained to generate multiple encodings for each input data sample. The multiple encodings are usable together or separately by a decoder to reproduce a representation of the data sample. For example, a transmitting device can use an MDC network to generate two encodings of a data sample. In this example, the two encodings can be sent in two data packets (one encoding per data packet) to a receiving device. Continuing this example, if the receiving device receives both data packets, the two encodings can be combined to generate input data for a decoder of the receiving device. Alternatively, if only one of the data packets is received, the encoding in that data packet can be combined with filler data to generate input data for the decoder. In either of these cases, the data sample encoded by the transmitting device can be at least partially reconstructed. If both data packets are received, the data sample can be recreated with higher fidelity (e.g., a more accurate representation of the data sample can be recreated) than if only one of the data packets is received. However, since either of the encodings can be used separately, if one of the data packets is lost, recreating the data sample with lower fidelity is an improvement over a complete frame erasure. Note that in this example, no bandwidth is used to transmit replacement data (as would be the case in a retransmission scheme) or redundant data (as would be the case in a traditional forward error correction scheme). Thus, the bandwidth of the communication system is used more efficiently. Additionally, power that would be used to transmit replacement data or redundant data is conserved.

Unless expressly limited by its context, the term “generating” is used herein to indicate any of its ordinary meanings, such as computing or otherwise producing. Unless expressly limited by its context, the term “calculating” is used herein to indicate any of its ordinary meanings, such as computing, evaluating, smoothing, and/or selecting from a plurality of values. Unless expressly limited by its context, the term “obtaining” is used to indicate any of its ordinary meanings, such as calculating, deriving, receiving (e.g., from another component, block, or device), and/or retrieving (e.g., from a memory register or an array of storage elements).

Unless expressly limited by its context, the term “producing” is used to indicate any of its ordinary meanings, such as calculating, generating, and/or providing. Unless expressly limited by its context, the term “providing” is used to indicate any of its ordinary meanings, such as calculating, generating, and/or producing. Unless expressly limited by its context, the term “coupled” is used to indicate a direct or indirect electrical or physical connection. If the connection is indirect, there may be other blocks or components between the structures being “coupled.” For example, a loudspeaker may be acoustically coupled to a nearby wall via an intervening medium (e.g., air) that enables propagation of waves (e.g., sound) from the loudspeaker to the wall (or vice-versa).

The term “configuration” may be used in reference to a method, apparatus, device, system, or any combination thereof, as indicated by its particular context. Where the term “comprising” is used in the present description and claims, it does not exclude other elements or operations. The term “based on” (as in “A is based on B”) is used to indicate any of its ordinary meanings, including the cases (i) “based on at least” (e.g., “A is based on at least B”) and, if appropriate in the particular context, (ii) “equal to” (e.g., “A is equal to B”). In the case (i) where A is based on B includes based on at least, this may include the configuration where A is coupled to B. Similarly, the term “in response to” is used to indicate any of its ordinary meanings, including “in response to at least.” The term “at least one” is used to indicate any of its ordinary meanings, including “one or more”. The term “at least two” is used to indicate any of its ordinary meanings, including “two or more”.

The terms “apparatus” and “device” are used generically and interchangeably unless otherwise indicated by the particular context. Unless indicated otherwise, any disclosure of an operation of an apparatus having a particular feature is also expressly intended to disclose a method having an analogous feature (and vice versa), and any disclosure of an operation of an apparatus according to a particular configuration is also expressly intended to disclose a method according to an analogous configuration (and vice versa). The terms “method,” “process,” “procedure,” and “technique” are used generically and interchangeably unless otherwise indicated by the particular context. The terms “element” and “module” may be used to indicate a portion of a greater configuration. The term “packet” may correspond to a unit of data that includes a header portion and a payload portion. Any incorporation by reference of a portion of a document shall also be understood to incorporate definitions of terms or variables that are referenced within the portion, where such definitions appear elsewhere in the document, as well as any figures referenced in the incorporated portion.

As used herein, the term “communication device” refers to an electronic device that may be used for voice and/or data communication over a wireless communication network. Examples of communication devices include speaker bars, smart speakers, cellular phones, personal digital assistants (PDAs), handheld devices, headsets, wireless modems, laptop computers, personal computers, etc.

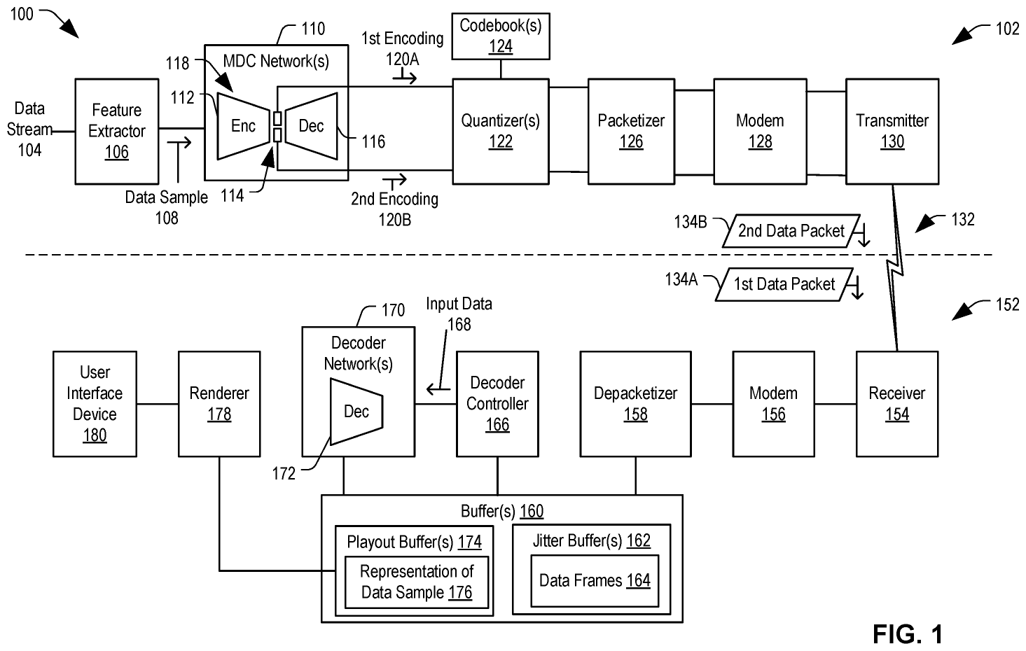

FIG. 1 is a diagram of a particular illustrative example of a system 100 including two or more devices configured to communicate via transmission of encoded data. The example of FIG. 1 shows a first device 102 that is configured to encode and transmit data and a second device 152 that is configured to receive, decode, and use the data. For ease of reference herein, the first device 102 is also referred to herein as an encoding device and/or a transmitting device, and the second device 152 is also referred to herein as a decoding device and/or receiving device. Although the system 100 illustrates one transmitting device 102, the system 100 can include more than one transmitting device 102. For example, a two-way communication system may include two devices (e.g., mobile phones), and each of the devices may transmit data to and receive data from the other device. That is, each device may act as both a transmitting device 102 and a receiving device 152. In another example, a single receiving device 152 can receive data from more than one transmitting device 102. Additionally, or alternatively, the system 100 can include more than one receiving device 152. For example, a single transmitting device 102 may transmit (e.g., multicast or broadcast) data to multiple receiving devices 152. Thus, the one-to-one pairing of the transmitting device 102 and the receiving device 152 illustrated in FIG. 1 is merely illustrative of one configuration and is not limiting.

In the example of FIG. 1, the transmitting device 102 includes a plurality of components arranged to obtain data from a data stream 104 and to process the data to generate data packets (e.g., a first data packet 134A and a second data packet 134B) that are transmitted over a transmission medium 132. In FIG. 1, the components of the transmitting device 102 include a feature extractor 106, one or more multiple description coding (MDC) networks 110, one or more quantizers 122, one or more codebooks 124, a packetizer 126, a modem 128, and a transmitter 130. In other examples, the transmitting device 102 may include more, fewer, or different components. To illustrate, in some examples, the transmitting device 102 includes one or more data generation devices configured to generate the data stream 104. Examples of such data generation devices include, for example and without limitation, microphones, cameras, game engines, media processors (e.g., computer-generated imagery engines), augmented reality engines, sensors, or other devices and/or instructions that are configured to output the data stream 104. To further illustrate, in some examples, the transmitting device 102 includes a transceiver instead of the transmitter 130 (or in which the transmitter 130 is disposed).

The data stream 104 in FIG. 1 includes data arranged in a time series. For example, the data stream 104 may include a sequence of data frames, where each data frame represents a time-windowed portion of data. In some examples, the data includes media data, such as voice data, audio data, video data, game data, augmented reality data, other media data, or combinations thereof.

The feature extractor 106 is configured to generate data samples (such as representative data sample 108) based on the data stream 104. The data sample 108 includes data representing a portion (e.g., a single data frame, multiple data frames, or a segment or subset of a data frame) of the data stream 104. The feature extraction technique(s) used by the feature extractor 106 may include, for example, data aggregation, interpolation, compression, windowing, domain transformation, sampling, smoothing, statistical analysis, etc. To illustrate, when the data stream 104 includes voice data or other audio data, the feature extractor 106 may be configured to determine time-domain or frequency-domain spectral information descriptive of a time-windowed portion of the data stream 104. In this example, the data sample 108 may include the spectral information. As one non-limiting example, the data sample 108 may include data describing a cepstrum of voice data of the data stream 104, data describing pitch associated with the voice data, other data indicating characteristics of the voice data, or a combination thereof. As another illustrative example, when the data stream 104 includes video data, game data, or both, the feature extractor 106 may be configured to determine pixel information associated with an image frame of the data stream 104. In the same or other examples, the data sample 108 may include other information, such as metadata associated with the data stream 104, compression data (e.g., keyframe identifiers), or other information used by the MDC network(s) 110 to encode the data sample 108.

Each of the one or more MDC networks 110 includes at least a multiple description coding encoder network, such as representative encoder (ENC) 112 of FIG. 1. A multiple description coding encoder network is a neural network that is configured to generate multiple encodings for each input data sample 108. For example, in FIG. 1, the encoder 112 is illustrated as generating two encodings (e.g., a first encoding 120A and a second encoding 120B) based on the data sample 108. The encodings generated based on a single data sample 108 are distinct from one another, and each is at least partially redundant to the others.

The encodings 120 are distinct in that they include separate data values. To illustrate, in some implementations, each encoding 120 is an array of values (e.g., floating point values), and the first encoding 120A includes one or more values that are different from one or more values of the second encoding 120B. In some implementations, the encodings 120 are different sizes (e.g., the array of the first encoding 120A has a first count of values and the array of the second encoding 120B has a second count of values, where the first count of values is not equal to the second count of values).

The encodings 120 are at least partially redundant to one another in that any individual encoding 120 can be decoded alone, or with other encodings, to approximately reproduce the data sample 108. Decoding more of the encodings 120 together generates a higher quality (e.g., more accurate) approximation of the data sample 108 than decoding fewer of the encodings 120 together. As explained further below, the encodings 120 can be sent in different data packets 134 so that the receiving device 152 can use all of the encodings 120 together to generate a high quality reproduction of the data sample 108, or if the receiving device 152 does not receive one or more of the data packets 134 in a timely manner, the receiving device 152 can use fewer than all of the encodings 120 to generate a lower quality reproduction of the data sample 108.

The encoder 112 is illustrated in FIG. 1 as an encoder portion of an autoencoder 118 that includes a bottleneck layer 114 and a decoder (“DEC”) portion 116. The decoder portion 116 is represented in FIG. 1 to facilitate discussion of one mechanism for generating and/or training the encoder 112 and for generating and/or training a decoder 172 to be used by the receiving device 152. In some implementations, the encoder 112, the bottleneck layer 114, and the decoder portion 116 are trained together using autoencoder training techniques. For example, during training, a training data sample may be provided as input to the encoder 112. In this example, the encoder 112 being trained generates multiple encodings based on the training data sample. One or more of the multiple encodings are provided as input to the decoder portion 116 to generate output representing a reproduced version of the training data sample. An error metric is determined by comparing the training data sample and the reproduced version of the training data sample. Through multiple training iterations, parameters (such as link weights) of the autoencoder 118 are updated to reduce the error metric. By varying the number of encodings provided to the decoder portion 116 during training, the autoencoder 118 is trained to approximate the data sample 108 even if fewer than all of the encodings are input to the decoder portion 116.

After training, the decoder portion 116 can be replicated and provided to one or more devices for use as the decoder 172. During operation of the transmitting device 102, the decoder portion 116 may be omitted or unused. Alternatively, the decoder portion 116 may be present and used to provide feedback to the encoder 112. To illustrate, in some implementations, the autoencoder 118 may include or correspond to a feedback recurrent autoencoder. In such implementations, the feedback recurrent autoencoder may output state data associated with one or more data samples and may provide the state data as feedback data to the encoder 112, to the decoder portion 116, or both, to enable the autoencoder 118 to encode and/or decode a data sample in a manner that accounts for previously encoded/decoded data samples.

In some implementations, the MDC network(s) 110 include more than one autoencoder 118 or more than one encoder 112. For example, the MDC network(s) 110 may include an encoder 112 for audio data and a different encoder for other type of data. As another example, the encoder 112 may be selected from among multiple encoders depending on a count of bits to be allocated to representing the encodings 120. As another example, the MDC network(s) 110 may include two or more encoders, and the encoder 112 used at a particular time may be selected from among the two or more encoders based on characteristics of the data stream 104, characteristics of the data sample 108, characteristics of the transmission medium 132, capabilities of the receiving device 152, or a combination thereof.

As an illustrative example, a first encoder may be selected if the data stream 104 or the data sample 108 has characteristics that meet a selection criterion, and a second encoder may selected if the data stream 104 or the data sample 108 does not have characteristics that meet the selection criterion. In this example, the selection criterion may be based on the type(s) of data (e.g., audio data, game data, video data, etc.) in the data stream 104 or the data sample 108. Additionally or alternatively, the selection criterion may be based on a source of the data (e.g., whether the data stream is pre-recorded and rendered from a memory device or the data stream represents live-captured media). Additionally or alternatively, the selection criterion may be based on a bit rate or quality of the data stream 104 or the data sample 108. Additionally or alternatively, the selection criterion may be based on criticality of the data sample 108 to reproduction of the data stream 104. For example, during a voice conversation, many time-windowed data samples represent silence and accurate encoding of such data samples may be less important to reproduction of speech than other data samples extracted from the data stream 104.

As another illustrative example, a first encoder may be selected if the transmission medium 132 has characteristics that meet a selection criterion, and a second encoder may be selected if the transmission medium 132 does not have characteristics that meet the selection criterion. In this example, the selection criterion may be based on the bandwidth of the transmission medium 132, one or more packet loss metrics (or one or more metrics that are indicative of probability of packet loss), one or more metrics indicative of the quality of the transmission medium 132, etc.

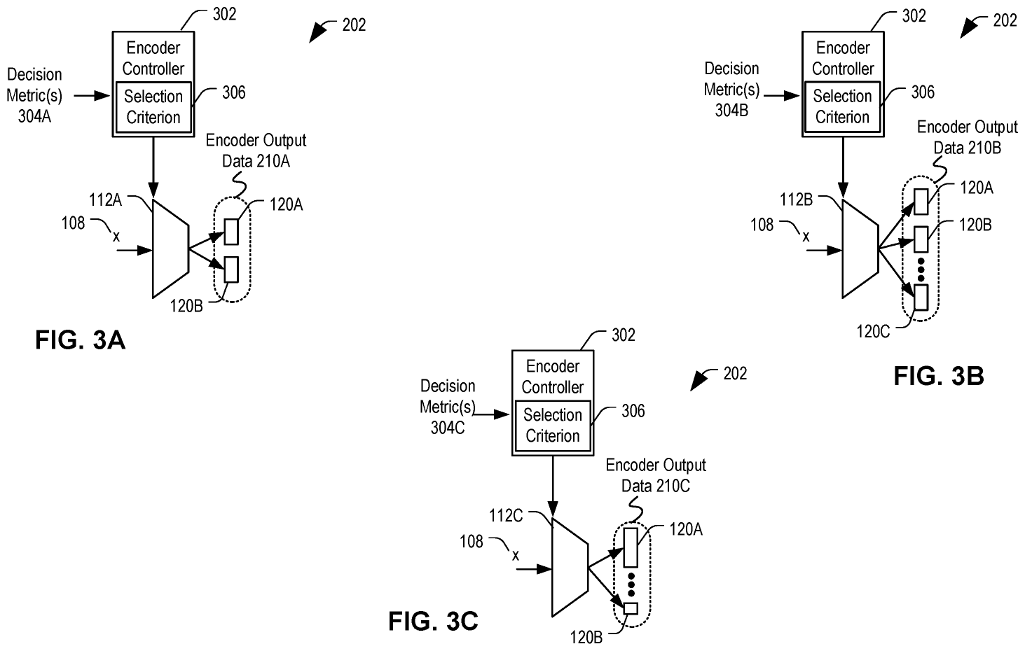

When the MDC network(s) 110 include two or more encoders 112, the two or more encoders 112 may have different split configurations for generating encodings 120. In this context, the “split configuration” of an encoder 112 indicates the size (e.g., number of nodes) of the bottleneck layer 114, how many encodings 120 are generated at the bottleneck layer 114, and which nodes of the bottleneck layer 114 generate each encoding 120. For example, in FIG. 1, the bottleneck layer 114 is illustrated as divided approximately evenly into two portions, and each portion generates a respective encoding 120. However, as explained further with reference to FIGS. 3A-3C, the nodes of the bottleneck layer 114 can be divided into more than two portions (again with each portion generating a respective encoding 120). Further, the nodes of the bottleneck layer 114 need not be divided evenly. For example, the first encoding 120 may include or correspond to an array of twenty data values, and the second encoding 120B may include or correspond to an array of ten data values.

The quantizer(s) 122 are configured to use the codebook(s) 124 to map values of the encodings 120 to representative values. For example, each encoding 120 may include an array of floating point values, and the quantizer(s) 122 map each floating point value of an encoding 120 to a representative value of the codebook(s) 124. In a particular aspect, each of the encodings 120 is quantized independently of the other encoding(s) 120. For example, the content of the first encoding 120A does not affect quantization of the second encoding 120B, and vice versa. One or more of the quantizer(s) 122 may use a single stage quantization operation (e.g., are single-stage quantizers). Additionally, or alternatively, one or more of the quantizer(s) 122 may use a multiple stage quantization operation (e.g., are multi-stage quantizers).

In some implementations, a single quantizer 122 and/or a single codebook 124 is used for each of the encodings 120 from a particular encoder 112. For example, each encoder 112 may be associated with a corresponding codebook 124 and all encodings generated by a particular encoder 112 are quantized using the corresponding codebook 124. In such implementations, if the MDC network(s) 110 include multiple encoders 112, the single quantizer 122 and the single codebook 124 may also be used to quantize encodings 120 generated by one or more of the other encoders 112. For example, the MDC networks 110 may include a plurality of encoders 112, and a single quantizer 122 and/or a single codebook 124 may be used for all of the plurality of encoders 112 (e.g., one codebook 124 shared by all of the encoders 112). In another example, the MDC networks 110 may include a plurality of encoders 112, and a single quantizer 122 and/or a single codebook 124 may be used for two or more encoders 112 of the plurality of encoders 112, and one or more additional quantizers 122 and/or codebooks 124 may be used for the remaining encoders 112 of the plurality of encoders 112.

According to some aspects, the number of encodings 120 generated by an encoder 112 is based on a split configuration of the bottleneck layer 114 associated with the encoder 112. For example, the bottleneck layer 114 may be split (evenly or unevenly) into multiple portions such that each portion generates output data corresponding to one of the encodings 120. In some implementations, each respective portion of the bottleneck layer 114 may be associated with a corresponding quantizer 122 and/or codebook 124. For example, a first portion of the bottleneck layer 114 associated with an encoder 112 may be configured to output the first encoding 120A and may be associated with a first codebook 124, and a second portion of the bottleneck layer 114 associated with the encoder 112 may be configured to output the second encoding 120B and may be associated with a second codebook 124. Additionally, or alternatively, the first portion of the bottleneck layer 114 may be associated with a first quantizer 122, and a second portion of the bottleneck layer 114 may be associated with a second quantizer 122.

The packetizer 126 is configured to generate a plurality of data packets based on the quantized encodings. In a particular aspect, the encodings 120 for a particular data sample 108 are distributed among two or more data packets. For example, a quantized representation of the first encoding 120A of the data sample 108 may be included in a first data packet 134A and a quantized representation of the second encoding 120B of the data sample 108 may be included in a second data packet 134B. In some implementations, a payload portion of a single data packet may include encodings corresponding to two or more different data samples. The packetizer 126 appends header information to a payload that includes one or more quantized representations of encodings, and may, in some implementations, add other protocol specific information to form a data packet (such as zero-padding to complete an expected data packet size associated with a particular protocol).

The modem 128 is configured to modulate a baseband, according to a particular communication protocol, to generate signals representing the data packets. The transmitter 130 is configured to send the signals representing the data packets 134 via the transmission medium 132. The transmission medium 132 may include a wireline medium, an optical medium, or a wireless medium. To illustrate, the transmitter 130 may include or correspond to a wireless transmitter configured to send the signals via free-space propagation of electromagnetic waves.

In the example of FIG. 1, the receiving device 152 is configured to receive the data packets 134 from the transmitting device 102. As noted above, the transmission medium 132 may be lossy. For example, one or more of the data packets 134 may be delayed during transmission or never received at the receiving device 152. The receiving device 152 includes a plurality of components arranged to process the data packets 134 that are received and to generate output based on the received data packets 134

In FIG. 1, the components of the receiving device 152 include a receiver 154, a modem 156, a depacketizer 158, one or more buffers 160, a decoder controller 166, one or more decoder networks 170, a renderer 178, and a user interface device 180. In other examples, the receiving device 152 may include more, fewer, or different components. To illustrate, in some examples, the receiving device 152 includes more than one user interface device 180, such as one or more displays, one or more speakers, one or more haptic output devices, etc. To further illustrate, in some examples, the receiving device 152 includes a transceiver instead of the receiver 154 (or in which the receiver 154 is disposed).

The receiver 154 is configured to receive the signals representative of data packets 134 and to provide the signals (after initial signal processing, such as amplification, filtering, etc.) to the modem 156. As noted above, the receiving device 152 may not receive all of the data packets 134 sent by the transmitting device 102. Additionally, or in the alternative, the data packets 134 may be received in a different order than they are transmitted by the transmitting device 102.

The modem 156 is configured to demodulate the signals to generate bits representing the received data packets and to provide the bits representing the received data packets to the depacketizer 158. The depacketizer 158 is configured to extract one or more data frames from the payload of each received data packets and to store the data frames at the buffer(s) 160. For example, in FIG. 1, the buffer(s) 160 include a jitter buffer(s) 162 configured to store the data frames 164. The buffer(s) 160 store the data frame to enable reordering of the data frame 164, to allow time for delayed data frames to arrive, etc.

In the example illustrated in FIG. 1, a decoder controller 166 retrieves data from the buffer(s) 160 to generate input data 168 for the decoder network(s) 170. In some implementations, the decoder controller 166 also performs buffer management operations, such as managing a depth of the jitter buffer(s) 162, a depth of a playout buffer(s) 174, or both. If the decoder network(s) 170 include multiple decoders, the decoder controller 166 may also determine which of the decoders to use at a particular time.

To decode a particular data sample, the decoder controller 166 generates the input data 168 for a decoder 172 of the decoder networks 170 based on available data frames (if any) associated with the particular data sample. For example, the decoder controller 166 combines two or more data portions to form the input data 168. Each data portion corresponds to filler data or to a data frame (e.g., data representing one of the encodings 120) associated with the particular data sample that has been received at the receiving device 152 and stored at the buffer(s) 160. A count of data portions of the input data 168 for the particular data sample corresponds to the count of encodings 120 generated by the encoder 112 for the particular data sample. The count of the encodings 120 may be indicated via in-band communications, such as in the data packets 134 sent by the transmitting device 102, or via out-of-band communications, such as during set up or update of communication session parameters between the transmitting device 102 and the receiving device 152 (e.g., as part of a handshake and/or negotiation process).

To generate the input data 168, the decoder controller 166 determines, based on playout sequence information (e.g., a playout time or a playout sequence) associated with the data frames 164, a next data sample that is to be decoded. The decoder controller 166 determines whether any data frame associated with the next data sample is stored in the buffer(s) 160. If all data frames associated with the next data sample are available (e.g., stored in the buffer(s) 160), the decoder controller 166 combines the data frames to generate the input data 168. If at least one data frame associated with the next data sample is available and at least one data frame associated with the next data sample is not available (e.g., is not stored in the buffer(s) 160), the decoder controller 166 combines the available data frames associated with the next data sample with filler data to generate the input data 168. If no data frame associated with the next data sample is available (e.g., stored in the buffer(s) 160), the decoder controller 166 uses filler data to generate the input data 168. The filler data may include a predetermined set of values (e.g., zero padding) or may be determined based on available data frames associated with another data sample (e.g., a previously decoded data sample, a yet to be decoded data sample, or interpolation data therebetween).

As a non-limiting example, the data sample 108 illustrated in FIG. 1 may be encoded to generate a first encoding 120A and a second encoding 120B. In this example, data representing the first encoding 120A is sent via the first data packet 134A and data representing the second encoding 120B is sent via the second data packet 134B. In a first circumstance, the receiving device 152 receives the first and second data packets 134A, 134B in a timely manner, then at a decoding time associated with the data sample 108, the data frames 164 in the buffer(s) 160 include a first data frame corresponding to the data representing the first encoding 120A and a second data frame corresponding to the data representing the second encoding 120B. In the first circumstance, the decoder controller 166 generates the input data 168 by combining a first data portion corresponding to the first data frame and a second data portion corresponding to the second data frame.

Continuing this non-limiting example, in a second circumstance, the receiving device 152 receives one of the data packets 134 (such as the first data packet 134A) in a timely manner but does not receive the other data packet 134 (such as the second data packet 134B) in a timely manner. In the second circumstance, at a decoding time associated with the data sample 108, the data frames 164 in the buffer(s) 160 include the first data frame corresponding to the data representing the first encoding 120A and do not include the second data frame corresponding to the data representing the second encoding 120B. In the second circumstance, the decoder controller 166 generates the input data 168 by combining a first data portion corresponding to the first data frame and filler data. The filler data in the second circumstance may be determined from a second data frame that is available in the buffer(s) 160, such as a second data frame of a previously decoded data sample. Alternatively, the filler data may include zero padding or other predetermined values.

Continuing this non-limiting example, in a third circumstance, the receiving device 152 does not receive any of the data packets 134 associated with the data sample 108 in a timely manner. In the third circumstance, at a decoding time associated with the data sample 108, the data frames 164 in the buffer(s) 160 do not include any data frame corresponding to the data representing the encodings 120, and the decoder controller 166 generates the input data 168 using filler data. The filler data in the third circumstance may be determined based on data frames that are available in the buffer(s) 160, such as data frames of a previously decoded data sample. Alternatively, the filler data may include zero padding or other predetermined values.

The decoder controller 166 provides the input data 168 as input to the decoder 172, and based on the input data 168, the decoder 172 generates output data representing the data sample, which may be stored at the buffer(s) 160 (e.g., at one or more playout buffers 174) as a representation of the data sample 176. According to some aspects, the decoder 172 is an instance of the decoder portion 116 of an autoencoder that includes the encoder 112 used to encode the data sample 108. As used herein, a “representation of the data sample” refers to data that approximates the data sample 108. For example, if the data sample 108 is an image frame, the representation of the data sample 176 is an image frame that approximates the original image frame of the data sample 108. Generally, the representation of the data sample 176 is not an exact replica of the original data sample 108 due to losses associated with encoding, quantizing, transmitting, and decoding. However, during normal operation (e.g., when the transmission medium 132 is not too lossy), the representation of the data sample 176 matches the data sample 108 sufficiently that differences during rendering may be below human perceptual limits.

At a playback time associated with a particular data sample 108, the renderer 178 retrieves a corresponding representation of the data sample 176 from the buffer(s) 160 and processes the representation of the data sample 176 to generate output signals, such as audio signals, video signals, game update signals, etc. The renderer 178 provides the signals to a user interface device 180 to generate a user perceivable output based on the representation of the data sample 176. For example, the user perceivable output may include one or more of a sound, an image, or a vibration. In some implementations, the renderer 178 includes or corresponds to a game engine that generates the user perceivable output in response to modifying a game state based on the representation of the data sample 176.

In some implementations, the decoder 172 corresponds to a decoder portion of a feedback recurrent autoencoder. In such implementations, decoding the input data 168 may cause a state of the decoder 172 to change. In such implementations, using filler data for one or more data portions of the input data 168 results in a slightly different state change than would result if all of the data portions of the input data 168 corresponded to data frames associated with the data sample 108. Such differences in the state may, at least in the short term, decrease reproduction fidelity of the decoder 172 for subsequent data samples.

For example, in a particular circumstance, decoding operations for a first data sample may be performed at a time when at least one data frame associated with the first data sample is unavailable. In this circumstance, filler data may be used in place of the unavailable data frame(s), and the input data 168 to the decoder 172 combines available data frames (if any) of the first data sample and the filler data. Based on the input data 168, the decoder 172 generates a representation of the first data sample and updates state data associated with the decoder 172. Subsequently, the decoder 172 uses the updated state data when performing decoding operations associated with a second data sample to generate a representation of the second data sample. The second data sample may be a data sample that immediately follows the first data sample, or one or more other data samples may be disposed between the first and second data samples. Because the updated state data is based in part on the filler data, the representation of the second data sample may be a lower quality (e.g., less accurate) reproduction of the second data sample.

In a particular aspect, lower quality reproduction of the second data sample can be at least partially mitigated if missing data frames associated with the first data sample are later received (e.g., after decoding operations associated with the first data sample have been performed). For example, in some circumstances, one of the data packets 134 is delayed too long to be used to decode the first data sample but is received before decoding of the second data sample. In such circumstances, a state of the decoder 172 can be reset (e.g., rewound) to a state that existed prior to decoding the first data sample. The decoder controller 166 can generate input data 168 for the decoder that is based on all available data frames (including the newly received late data frame(s)) and provide the input data 168 to the decoder 172. The decoder 172 generates an updated representation of the first data sample 176 and the state of the decoder 172 is updated. The updated representation of the first data sample 176 may be discarded if the previously generated representation of the first data sample 176 has already been played out; however, the updated state of the decoder 172 is used going forward, e.g., to perform decoding operations associated with the second data sample. Using the updated state of the decoder 172 to perform decoding operations associated with the second data sample results in a higher quality reproduction of the second data sample (as compared to using state data that is based in part on filler data).

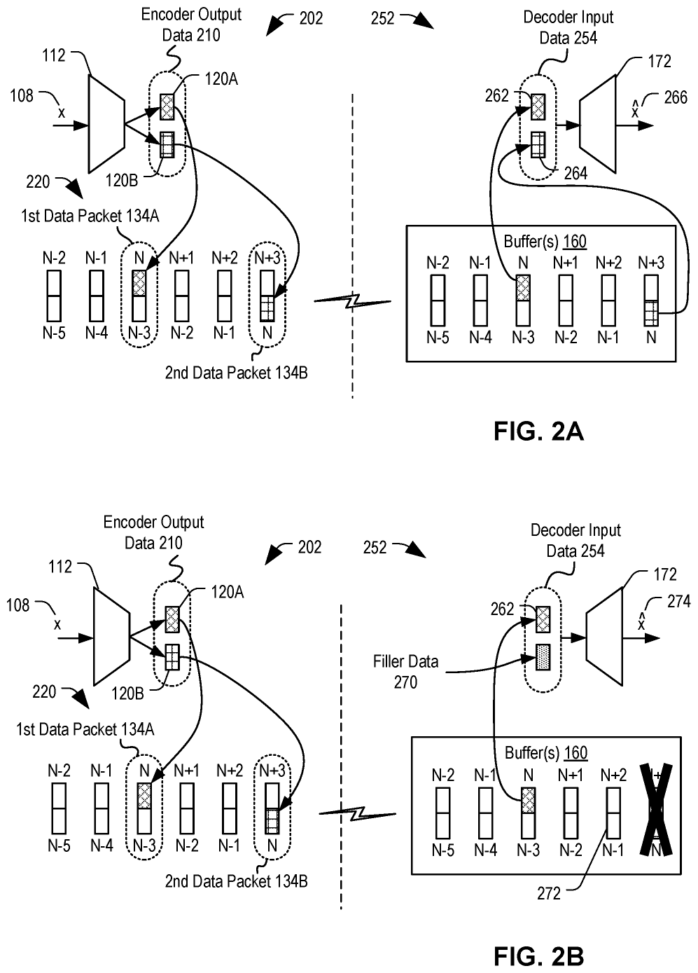

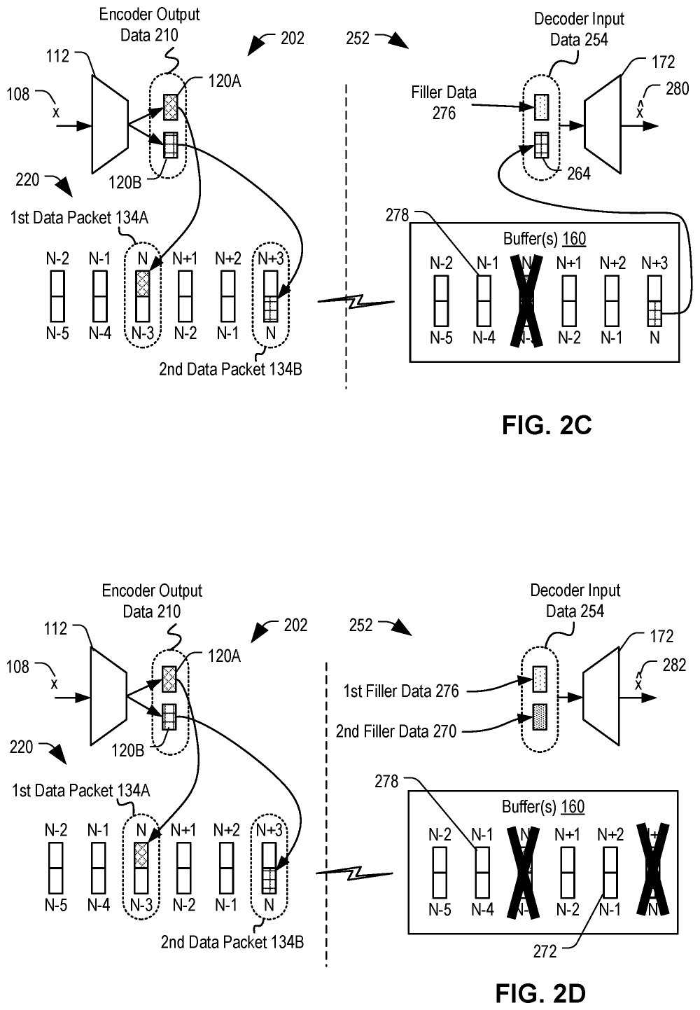

FIGS. 2A, 2B, 2C, and 2D are diagrams of examples of operation of the system 100 of FIG. 1. FIGS. 2A, 2B, 2C, and 2D include simplified representations of an encoding device 202 and a decoding device 252. In some implementations, the encoding device 202 includes, corresponds to, or is included within the transmitting device 102 of FIG. 1. In the same or different implementations, the decoding device 252 includes, corresponds to, or is included withing the receiving device 152 of FIG. 1.

The encoding device 202 of each of FIGS. 2A-2D includes the encoder 112, which is configured to receive the data sample 108. The encoder 112 generates encoder output data 210 corresponding to the data sample 108. The encoder output data 210 includes two or more distinct and at least partially redundant encodings, such as the first encoding 120A and the second encoding 120B.

The encoding device 202 is configured to generate a sequence of data packets 220 to send to the decoding device 252 via the transmission medium 132. Each data packet of the sequence of data packets 220 includes data for two or more encodings. Further, data representing the encodings 120 of a single data sample 108 are sent via different data packets 134. To illustrate, each of FIGS. 2A-2D shows six data packets of the sequence of data packets 220, and each data packet of the sequence of data packets 220 includes data for two encodings that are derived from different data samples. Data representing the first encoding 120A for the data sample 108 is included in the first data packet 134A, and data representing the second encoding 120B for the data sample 108 is included in the second data packet 134B. The first data packet 134A and the second data packet 134B are offset from one another in the sequence of data packets 220. For example, in FIGS. 2A-2D, there are two data packets between the first data packet 134A and the second data packet 134B. In other examples, the first and second data packets 134A, 134B are offset by more than two data packets or fewer than two data packets.

FIG. 2A illustrates operation of the decoder 172 in a first circumstance in which the decoding device 252 receives both the first data packet 134A and the second data packet 134B in a timely manner. In the first circumstance, at a decoding time associated with the data sample 108, the buffer(s) 160 include data frames corresponding to or representing the first encoding 120A and the second encoding 120B, and the decoder controller 166 of FIG. 1 (not shown in FIGS. 2A-2D) generates decoder input data 254 based on the data frames. Thus, in the first circumstance, the decoder input data 254 include a first portion 262 that corresponds to or represents the first encoding 120A and a second portion 264 that corresponds to or represents the second encoding 120B. The decoder 172 generates decoder output 266, that approximates the data sample 108, based on the decoder input data 254.

FIG. 2B illustrates operation of the decoder 172 in a second circumstance in which the decoding device 252 receives the first data packet 134A in a timely manner but does not receive the second data packet 134B in a timely manner. In the second circumstance, at a decoding time associated with the data sample 108, the buffer(s) 160 include a data frame corresponding to or representing the first encoding 120A, but do not include a data frame corresponding to or representing the second encoding 120B. In FIG. 2B, a first portion 262 of the decoder input data 254 includes data corresponding to or representing the first encoding 120A, and a second portion of the decoder input data 254 includes filler data 270. For example, the filler data 270 may include predetermined values, such as zero-padding, or may include values determined based on another data frame. To illustrate, in FIGS. 2A-2D, the data sample 108 is the Nth data sample, and the filler data 270 may be determined based on data associated with an earlier data sample (such as a N−1th data sample), a later data sample (such as an N+1th data sample), or both. For example, in FIG. 2B, a data frame 272 corresponding to or representing the second encoding of the N−1th data sample is available, and the data frame 272 may be used as the filler data 270 or used to determine the filler data 270. The decoder 172 generates decoder output 274 that approximates the data sample 108 based on the decoder input data 254. As compared to the decoder output 266 in the first circumstance, the decoder output 274 may be a somewhat less accurate approximation of the data sample 108.

FIG. 2C illustrates operation of the decoder 172 in a third circumstance in which the decoding device 252 receives the second data packet 134B in a timely manner but does not receive the first data packet 134A in a timely manner. In the third circumstance, at a decoding time associated with the data sample 108, the buffer(s) 160 include a data frame corresponding to or representing the second encoding 120B, but do not include a data frame corresponding to or representing the first encoding 120A. In FIG. 2C, a first portion of the decoder input data 254 includes filler data 276, and a second portion of the decoder input data 254 includes data corresponding to or representing the second encoding 120B. For example, the filler data 276 may include predetermined values, such as zero-padding, or may include values determined based on another data frame. To illustrate, in FIGS. 2A-2D, the data sample 108 is the Nth data sample, and the filler data 276 may be determined based on data associated with an earlier data sample (such as a N−1th data sample), a later data sample (such as an N+1th data sample), or both. For example, in FIG. 2C, a data frame 278 corresponding to or representing a first encoding of the N−1th data sample is available, and the data frame 278 may be used as the filler data 276 or used to determine the filler data 276. The decoder 172 generates decoder output 280 that approximates the data sample 108 based on the decoder input data 254. As compared to the decoder output 266 in the first circumstance, the decoder output 280 may be a somewhat less accurate approximation of the data sample 108.

FIG. 2D illustrates operation of the decoder 172 in a fourth circumstance in which the decoding device 252 does not receive the first data packet 134A or the second data packet 134B in a timely manner. In the fourth circumstance, at a decoding time associated with the data sample 108, the buffer(s) 160 do not include a data frame corresponding to or representing the first encoding 120A and do not include a data frame corresponding to or representing the second encoding 120B. In FIG. 2D, a first portion of the decoder input data 254 includes filler data 276, and a second portion of the decoder input data 254 includes filler data 270. For example, each of the filler data 270 and 276 may include predetermined values, such as zero-padding, or may include values determined based on another data frame. To illustrate, in FIGS. 2A-2D, the data sample 108 is the Nth data sample, and the filler data 270 and/or the filler data 276 may be determined based on data associated with an earlier data sample (such as a N−1th data sample), a later data sample (such as an N+1th data sample), or both. For example, in FIG. 2D, a data frame 278 corresponding to or representing a first encoding of the N−1th data sample is available, and a data frame 272 corresponding to or representing a second encoding of the N−1th data sample is available. In this example, the data frame 278 may be used as first filler data 276 and the data frame 272 may be used as second filler data 270. The decoder 172 generates decoder output 282 that approximates the data sample 108 based on the decoder input data 254. As compared to the decoder output 266 in the first circumstance, the decoder output 282 may be a somewhat less accurate approximation of the data sample 108. Further, the decoder output 282 may be a less accurate approximation of the data sample 108 than either or both of the decoder output 274 and 280.

In some implementations, the encoder 112 generates more than two encodings per data sample 108. In such implementations, the decoder input data 254 for a particular data sample 108 includes each data frame associated with the particular data sample 108 that is available at a decoding time associated with the particular data sample 108 and includes filler data for each data frame associated with the particular data sample 108 that is not available at the decoding time associated with the particular data sample 108.

FIGS. 3A, 3B, and 3C are diagrams of particular examples of aspects of operation of an encoding device of the system of FIG. 1. In particular, FIGS. 3A, 3B, and 3C include simplified representations of the encoding device 202. In some implementations, the encoding device 202 includes, corresponds to, or is included within the transmitting device 102 of FIG. 1.

The encoding device 202 of each of FIGS. 3A-3C includes an encoder controller 302 that is configured to select a particular encoder 112 (e.g., encoder 112A of FIG. 3A, encoder 112B of FIG. 3B, or encoder 112C of FIG. 3C) from the MDC network(s) 110 of FIG. 1 based on one or more decision metrics 304. The encoders 112A, 112B, and 112C have different split configurations, where the split configuration indicates how the encoder output data 210 is divided among two or more encodings 120.

As a first example, in FIG. 3A, the encoder output data 210A includes two evenly split encodings 120. To illustrate, in FIG. 3A, an array corresponding to the first encoding 120A includes the same number of values as an array corresponding to the second encoding 120B.

As a second example, in FIG. 3B, the encoder output data 210B includes more than two encodings and such encodings are each of approximately the same size. To illustrate, in FIG. 3B, the encoder output data 210B includes a first encoding 120A, a second encoding 120B, and a third encoding 120C, and may also include one or more additional encodings as indicated by an ellipsis between the second encoding 120B and the third encoding 120C. In the second example, an array corresponding to the first encoding 120A includes the same number of values as an array corresponding to the second encoding 120B and the same number of values as an array corresponding to the third encoding 120C.

In a third example as illustrated by FIG. 3C, the encoder output data 210C includes two or more encodings of different sizes. To illustrate, in FIG. 3C, the encoder output data 210C includes a first encoding 120A and a second encoding 120B and may also include one or more additional encodings as indicated by an ellipsis between the first encoding 120A and the second encoding 120B. In the third example, an array corresponding to the first encoding 120A includes a different number of values from an array corresponding to the second encoding 120B. Further, if one or more additional encodings are present, the one or more additional encodings may correspond to arrays having the same number of values as the array corresponding to the first encoding 120A, may correspond to arrays having the same number of values as the array corresponding to the second encoding 120B, or may correspond to arrays having different numbers of values from the array corresponding to the first encoding 120A and the array corresponding to the second encoding 120B.

The encoder controller 302 may select an encoder 112 having a particular split configuration based on values of the decision metric(s) 304. To illustrate, the encoder controller 302 may compare one or more values of the decision metric(s) 304 to a selection criterion 306 and may select a particular encoder 112 from among multiple available encoders based on the comparison.

For example, the decision metric(s) 304 may include one or more values indicative of a data type or characteristics of the data stream 104 or the data sample 108. To illustrate, when the data stream 104 corresponds to a voice call, the decision metric(s) 304 may indicate whether the data sample 108 includes speech. As another illustrative example, the decision metric(s) 304 may indicate a type of data represented by the data stream 104, where types of data include, for example and without limitation, audio data, video data, game data, sensor data, or another data type. As another illustrative example, when the data stream 104 includes audio data, the decision metric(s) 304 may indicate a type or quality of the audio data, such as whether the audio data is monaural audio, stereo audio, spatial audio (e.g., ambisonics), etc. As another illustrative example, when the data stream 104 includes video data, the decision metric(s) 304 may indicate a type of quality of the video data, such as an image frame rate, an image resolution, whether the video as rendered is two dimensional (2D) or three dimensional (3D), etc.

As another example, the decision metric(s) 304 may include one or more values indicative of characteristics of the transmission medium 132. To illustrate, the decision metric(s) 304 may indicate a signal strength, a packet loss rate, a signal quality (e.g., a signal to noise ratio), or another characteristic of the transmission medium 132.

As another example, the decision metric(s) 304 may include one or more values indicating capabilities of a receiving device (e.g., the receiving device 152 of FIG. 1). To illustrate, the encoding device 202 may be capable of supporting a first set of communication protocols, and the receiving device 152 may be capable of supporting a second set of communication protocols. In this illustrative example, a negotiation process may be used to select a communication protocol that is supported by both devices, and the decision metric(s) 304 may identify the selected communication protocol. Additionally, or alternatively, the decision metric(s) 304 may include one or more values indicating how the encodings 120 are to be packetized, such as a count of bits per packet that is to be allocated to representing the encodings 120.

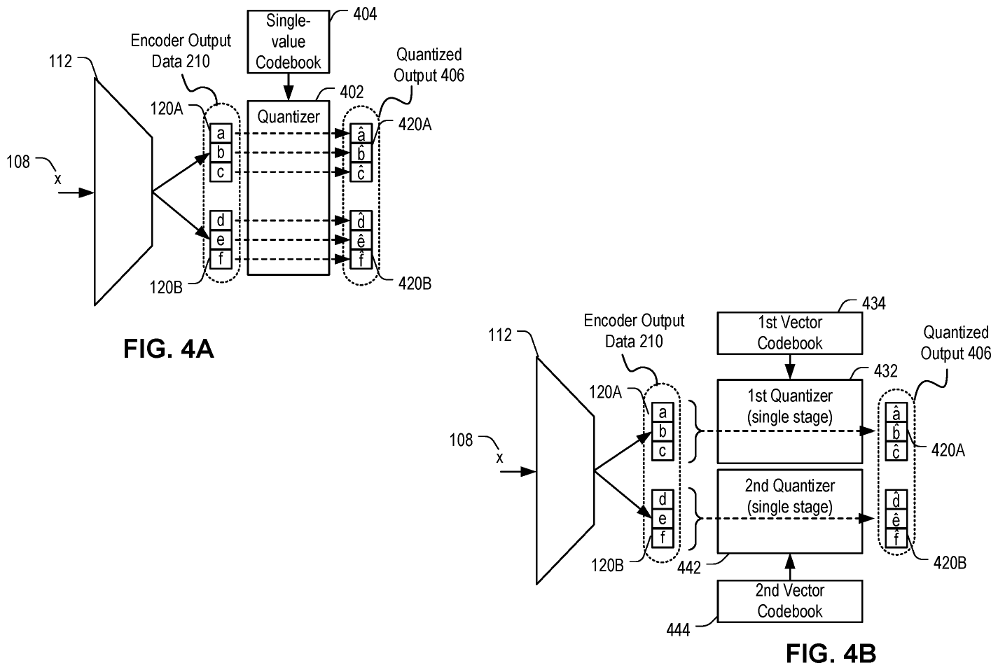

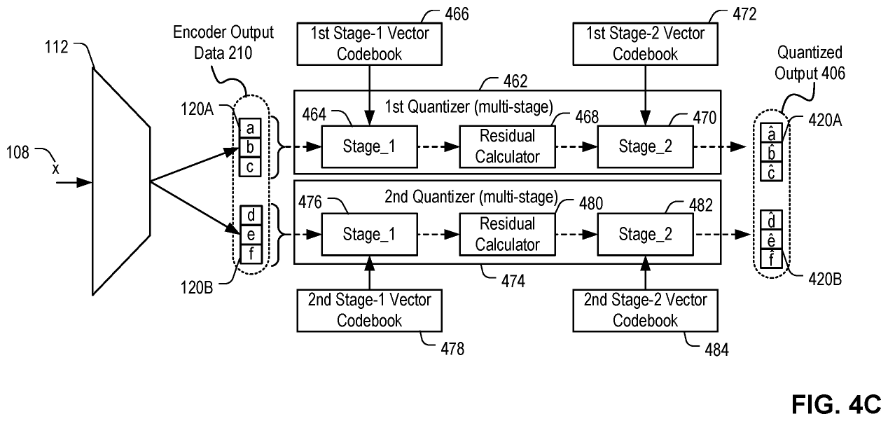

FIGS. 4A, 4B, and 4C are diagrams of particular examples of additional aspects of operation of an encoding device of the system of FIG. 1. In particular, FIGS. 4A, 4B, and 4C include simplified representations of the encoder 112 and quantizers, which together generate quantized output based on a data sample 108. In some implementations, the encoder 112 and quantizers of FIGS. 4A, 4B, and 4C are included within the transmitting device 102 of FIG. 1.

In each of FIGS. 4A-4C, the encoder 112 receives a data sample 108 as input and generates encoder output data 210 based on the data sample 108. The encoder 112 can include any of the encoders 112A-112C of FIGS. 3A-3C. Thus, for example, the encoder output data 210 may include two encodings 120 of the same size, two encodings 120 of different sizes, more than two encodings 120 of the same size, or more than two encodings 120 of two or more different sizes.

In FIG. 4A, a quantizer 402 uses a single-value codebook 404 to quantize all of the encodings 120 of the encoder output data 210 to generate quantized output 406. For example, the quantizer 402 uses the single-value codebook 404 to generate a quantized representation 420A of the first encoding 120A and uses the single-value codebook 404 to generate a quantized representation 420B of the second encoding 120B. In a particular aspect, the quantizer 402 corresponds to at least one of the quantizer(s) 122 of FIG. 1, and the single-value codebook 404 corresponds to a least one of the codebook(s) 124 of FIG. 1.

In FIG. 4B, each encoding 120 is quantized using a different codebook and a single stage quantizer. For example, a first quantizer 432 uses a first vector codebook 434 to determine first quantized values to quantize the first encoding 120A, and a second quantizer 442 uses a second vector codebook 444 to quantize the second encoding 120B. According to a particular, non-limiting example, different quantizers and/or different codebooks, as in FIG. 4B, may be used when the first encoding 120A and the second encoding 120B have different sizes. In a particular aspect, the first quantizer 432 and the second quantizer 442 correspond to two of the quantizer(s) 122 of FIG. 1, and the first vector codebook 434 and the second vector codebook 444 correspond to two of the codebook(s) 124 of FIG. 1.

In FIG. 4C, each encoding 120 is quantized using a respective multi-stage quantizer. For example, a first stage 464 of a first quantizer 462 uses a first stage-1 vector codebook 466 to determine a first approximation of the quantized representation 420A of the first encoding 120A. A residual calculator 468 determines residual value(s) based on the output of the first stage 464, and a second stage 470 uses a first stage-2 vector codebook 472 to quantize the residual value(s) and to generate the quantized representation 420A of the first encoding 120A. Similarly, in this example, a first stage 476 of a second quantizer 474 uses a second stage-1 vector codebook 478 to determine a first approximation of the quantized representation 420B of the second encoding 120B. A residual calculator 480 determines residual value(s) based on the output of the first stage 476, and a second stage 482 uses a second stage-2 vector codebook 484 to quantize the residual value(s) and to generate the quantized representation 420B of the second encoding 120B. In a particular aspect, the first quantizer 462 and the second quantizer 474 correspond to two of the quantizer(s) 122 of FIG. 1, and the first stage-1 vector codebook 466, the first stage-2 vector codebook 472, the second stage-1 vector codebook 478, and the second stage-2 vector codebook 484 correspond to several of the codebook(s) 124 of FIG. 1. Although FIG. 4C illustrates multistage quantizers 462, 474 with two stages each, the multistage quantizers 462, 474 may include more than two stages.

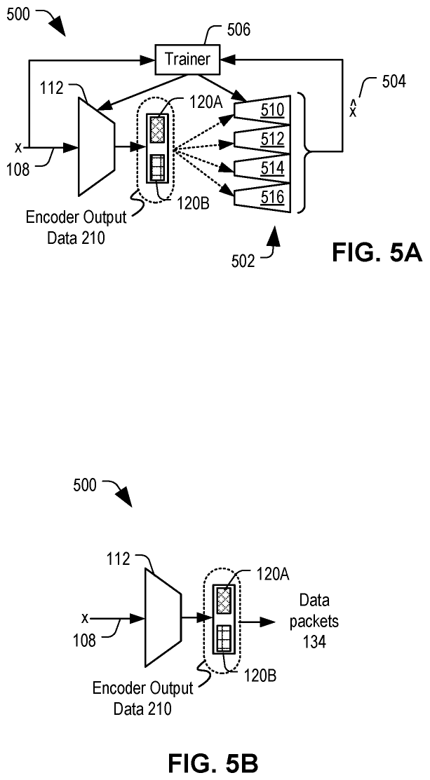

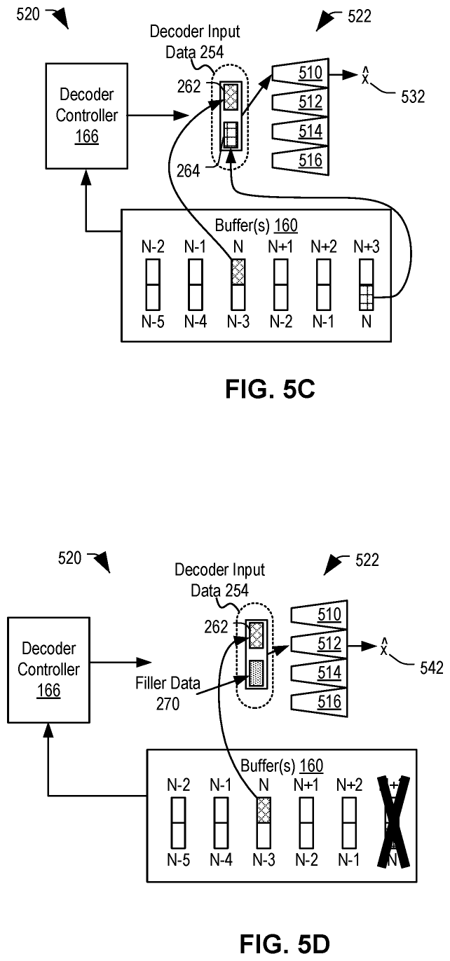

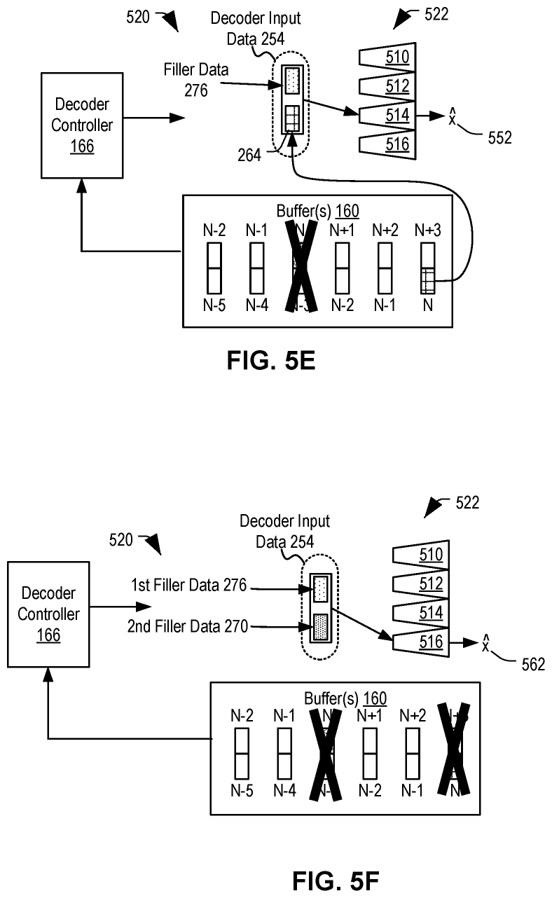

FIG. 5A is a diagram of a particular example of aspects of training an encoding device 500, FIG. 5B is a diagram of a particular example of aspects of operation of the encoding device 500, and FIGS. 5C-5F are diagrams of examples of aspects of operation of a decoding device 520. The encoding device 500 may correspond to, include, or be included within the transmitting device 102 of FIG. 1. Further, the decoding device 520 of FIGS. 5C-5F may correspond to, include, or be included within the receiving device 152 of FIG. 1. In FIGS. 5A and 5B, the encoder 112 of the encoding device 500 corresponds to an encoder portion of an autoencoder system that includes multiple decoder portions 502. In each of FIGS. 5C-5F, the decoding device 520 includes the multiple decoder portions 502, which are selectively used depending on which data frame(s) associated with a data sample 108 are available. FIGS. 5C-5F illustrate operations performed when various data frame(s) associated with the data sample 108 are available.

During training of the encoding device 500 as illustrated in FIG. 5A, the encoder 112 and the multiple decoder portions 502 are iteratively trained by a trainer 506. During a particular iteration of the iterative training, a data sample 108 is provided as input to the encoder 112, and the encoder 112 generates encoder output data 210 based on the data sample 108. As a non-limiting example, in FIG. 5A, the encoder output data 210 includes two encodings corresponding to a first encoding 120A and a second encoding 120B. As explained with reference to FIGS. 3A-3C, in other examples, the encoder output data 210 includes more than two encodings 120. Further, in some examples, the encodings 120 are the same size; whereas in other examples, two or more of the encodings 120 are different sizes.

During the particular training iteration, after the encoder output data 210 is generated, at least a portion of the encoder output data 210 is provided as input to at least one of the multiple decoder portions 502. In the non-limiting example illustrated in FIG. 5A, the multiple decoder portions 502 include a first decoder portion 510, a second decoder portion 512, a third decoder portion 514, and a fourth decoder portion 516. In this example, the first decoder portion 510 is configured to receive input including both the first encoding 120A and the second encoding 120B, the second decoder portion 512 is configured to receive input including the first encoding 120A and filler data, the third decoder portion 514 is configured to receive input including filler data and the second encoding 120B, and the fourth decoder portion 516 is configured to receive input including only filler data. Thus, the multiple decoder portions 502 in this example correspond to various circumstances that may be encountered by a decoder at a receiving device where all of the data frames associated with a data sample may be available, some of the data frames associated with the data sample may be available, or none of the data frames associated with the data sample may be available.

Output 504 generated by the selected one or more of the multiple decoder portions 502 is provided to the trainer 506. The trainer 506 calculates an error metric by comparing the data sample 108 to the output 504 (which is based on the data sample 108), and adjusts link weights or other parameters of the encoder 112 and/or the multiple decoder portions 502 to reduce the error metric. For example, the trainer 506 may use a gradient decent algorithm or a variant thereof (e.g., a boosted gradient decent algorithm) to adjusts link weights or other parameters of the encoder 112 and/or the multiple decoder portions 502. The training continues iteratively until a termination condition is satisfied. For example, the training may continue for a particular number of iterations, until the error metric is below a threshold, until a rate of change of the error metric between iterations satisfies a specified threshold, etc.

After training, the encoder 112, or the encoder 112 and the multiple decoder portions 502, may be used at an encoding device to prepare data for transmission to a decoding device (as described further below with reference to FIG. 5B). Additionally, the multiple decoder portions 502 may be used at a decoding device to decode data frames received from an encoding device (as described further with reference to FIGS. 5C-5F).

As illustrated in the example of FIG. 5B, during operation of the encoding device 500, the encoder 112 receives a data sample 108 as input and generates encoder output data 210 based on the data sample 108. In the example illustrated in FIG. 5B, the encoder output data 210 includes the first encoding 120A and the second encoding 120B, which the encoding device 500 uses to generate data packets 134, as explained above with reference to FIG. 1. The data sample 108 of FIG. 5B may be different from the data sample 108 of FIG. 5A used for training the encoder 112.

In some implementations, the encoding device 500 also includes the multiple decoder portions 502. In such implementation, the multiple decoder portions 502 provide feedback to the encoder 112. For example, the encoder 112 and the multiple decoder portions 502 may be configured to operate as a feedback recurrent autoencoder.

FIG. 5C illustrates operation of the decoding device 520 when all data frames corresponding to a particular data sample are available at a decoding time associated with the particular data sample. In FIG. 5C, the decoder controller 166 of the decoding device 520 assembles decoder input data 254 including a first portion 262 corresponding to the first encoding 120A associated with the data sample 108 and a second portion 264 corresponding to the second encoding 120B associated with the data sample 108. The decoder controller 166 selects a particular decoder portion from among a set of available decoder portions 522. In the examples illustrated in each of FIGS. 5C-5F, the set of available decoder portions 522 includes instances of each of the first decoder portion 510, the second decoder portion 512, the third decoder portion 514, and the fourth decoder portion 516 described with reference to FIG. 5A. In the example illustrated in FIG. 5C, the first decoder portion 510 is trained to decode decoder input data that includes all of the data frames associated with a particular data sample. Thus, since the decoder input data 254 includes all of the data frames associated with the data sample 108, the decoder controller 166 provides the decoder input data 254 to the first decoder portion 510, and the first decoder portion 510 generates an approximation 532 of the data sample 108 based on the decoder input data 254.

FIG. 5D illustrates operation of the decoding device 520 when a data frame representing a first encoding for a particular data sample is available and a second encoding for the particular data sample is not available at a decoding time associated with the particular data sample. In FIG. 5D, the decoder controller 166 of the decoding device 520 assembles decoder input data 254 including a first portion 262 corresponding to the first encoding 120A associated with the data sample 108 and a second portion that includes filler data 270. In the example illustrated in FIG. 5D, the second decoder portion 512 is trained to decode decoder input data that includes data representing the first encoding and filler data; therefore, the decoder controller 166 provides the decoder input data 254 to the second decoder portion 512. The second decoder portion 512 generates an approximation 542 of the data sample 108 based on the decoder input data 254. In this example, the approximation 542 may be a less accurate reproduction of the data sample 108 than the approximation 532 is. However, in some circumstances, the approximation 542 may be a more accurate reproduction of the data sample 108 than would be generated by the decoding device 252 of FIG. 2B, since the second decoder portion 512 has been trained for this specific situation whereas training of the decoder 172 of FIG. 2B is more general.

FIG. 5E illustrates operation of the decoding device 520 when a data frame representing a second encoding for a particular data sample is available and a first encoding for the particular data sample is not available at a decoding time associated with the particular data sample. In FIG. 5E, the decoder controller 166 of the decoding device 520 assembles decoder input data 254 including a first portion that includes filler data 276 and a second portion 264 corresponding to the second encoding 120B associated with the data sample 108. In the example illustrated in FIG. 5E, the third decoder portion 514 is trained to decode decoder input data that includes data representing the second encoding and filler data; therefore, the decoder controller 166 provides the decoder input data 254 to the third decoder portion 514. The third decoder portion 514 generates an approximation 552 of the data sample 108 based on the decoder input data 254. In this example, the approximation 552 may be a less accurate reproduction of the data sample 108 than the approximation 532 is. However, in some circumstances, the approximation 552 may be a more accurate reproduction of the data sample 108 than would be generated by the decoding device 252 of FIG. 2C, since the third decoder portion 514 has been trained for this specific situation whereas training of the decoder 172 of FIG. 2C is more general.

FIG. 5F illustrates operation of the decoding device 520 when no data frames representing encodings of a particular data sample are available. In FIG. 5F, the decoder controller 166 of the decoding device 520 assembles decoder input data 254 including a first portion that includes first filler data 276 and a second portion that includes second filler data 270. In the example illustrated in FIG. 5F, the fourth decoder portion 516 is trained to decode decoder input data that includes only filler data; therefore, the decoder controller 166 provides the decoder input data 254 to the fourth decoder portion 516. The fourth decoder portion 516 generates an approximation 562 of the data sample 108 based on the decoder input data 254. In this example, the approximation 562 may be a less accurate reproduction of the data sample 108 than the approximation 532 is. However, in some circumstances, the approximation 562 may be a more accurate reproduction of the data sample 108 than would be generated by the decoder 172 of FIG. 2D, since the fourth decoder portion 516 has been trained for this specific situation whereas training of the decoder 172 of FIG. 2D is more general.

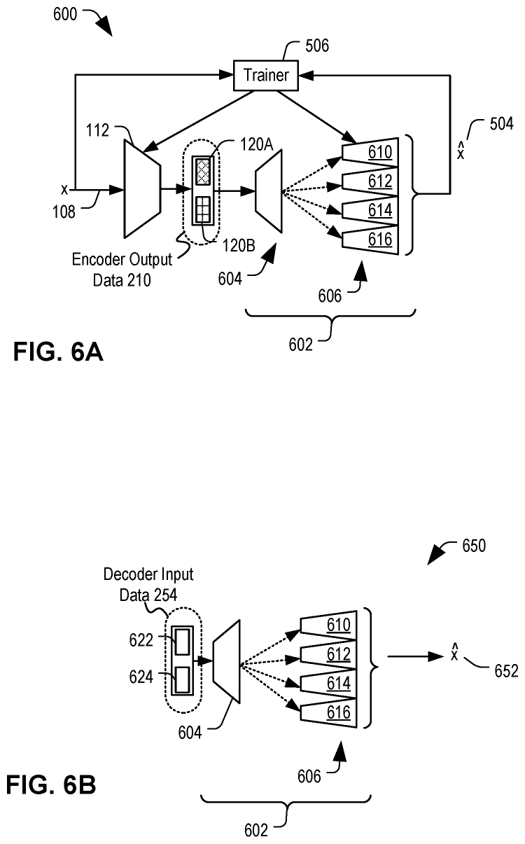

FIG. 6A is a diagram of a particular example of an additional aspect of operation of an encoding device 600, and FIG. 6B is a diagram of a particular example of an additional aspect of operation of a decoding device 650. The encoding device 600 may correspond to, include, or be included within the transmitting device 102 of FIG. 1, and the decoding device 650 may correspond to, include, or be included within the receiving device 152 of FIG. 1.

The encoding device 600 of FIG. 6A is similar to the encoding device 500 of FIGS. 5A and 5B except that a decoder 602 of the encoding device 600 includes one or more decoder layers 604 in addition to decoder portions 606 trained for specific circumstances. For example, in FIG. 6A, the one or more decoder layers 604 are configured to process the encoder output data 210, and output of the one or more decoder layers 604 is provided to one of the multiple decoder portions 606. In FIG. 6A, a first decoder portion 610 is configured to receive input based on processing of the first encoding 120A and the second encoding 120B by the one or more decoder layers 604, a second decoder portion 512 is configured to receive input based on processing of the first encoding 120A and filler data by the one or more decoder layers 604, the third decoder portion 514 is configured to receive input based on processing of filler data and the second encoding 120B by the one or more decoder layers 604, and the fourth decoder portion 516 is configured to receive input based on processing of only filler data by the one or more decoder layers 604. In other respects, the encoding device 600 operates as described with reference to the encoding device 500 of FIGS. 5A and 5B.

The decoding device 650 of FIG. 6B is similar to the decoding device 520 of FIGS. 5C-5F except that a decoder 602 of the decoding device 650 includes one or more decoder layers 604 in addition to decoder portions 606 trained for specific circumstances. For example, in FIG. 6B, the one or more decoder layers 604 are configured to process the decoder input data 254, and output of the one or more decoder layers 604 is provided to one of the multiple decoder portions 606. In FIG. 6B, a first decoder portion 610 is configured to receive input when a first portion 622 of the decoder input data 254 includes a data frame corresponding to a first encoding of a data sample and a second portion 624 of the decoder input data 254 includes a data frame corresponding to a second encoding of the data sample. Additionally, in FIG. 6B, a second decoder portion 612 is configured to receive input when the first portion 622 of the decoder input data 254 includes a data frame corresponding to a first encoding of the data sample and the second portion 624 of the decoder input data 254 includes filler data. Further, in FIG. 6B, a third decoder portion 614 is configured to receive input when the first portion 622 of the decoder input data 254 includes filler data and the second portion 624 of the decoder input data 254 includes a data frame corresponding to a second encoding of the data sample. Finally, in FIG. 6B, a fourth decoder portion 616 is configured to receive input when the first portion 622 of the decoder input data 254 includes filler data and the second portion 624 of the decoder input data 254 includes filler data. A selected one of the decoder portions 606 generates output data 652 based on the output of the one or more decoder layers 604. In other respects, the decoding device 650 operates as described with reference to the decoding device 520 of FIGS. 5C-5F.

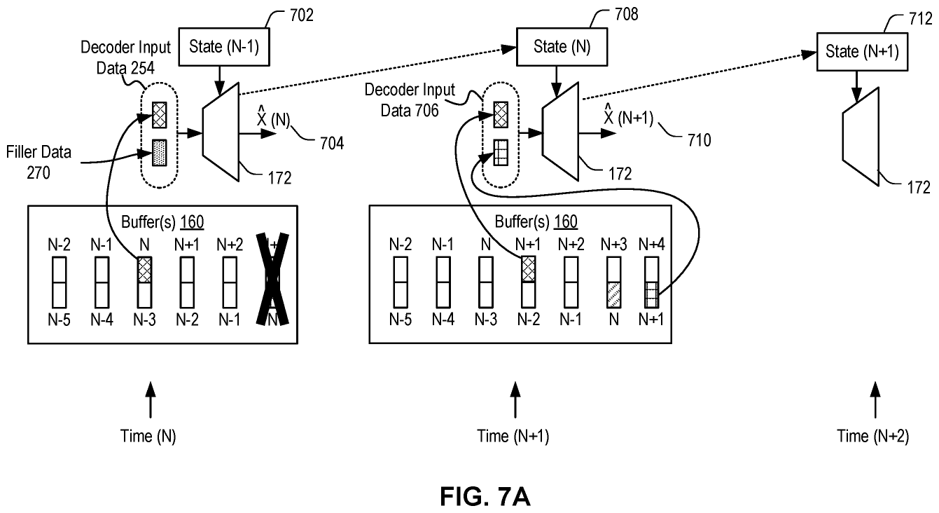

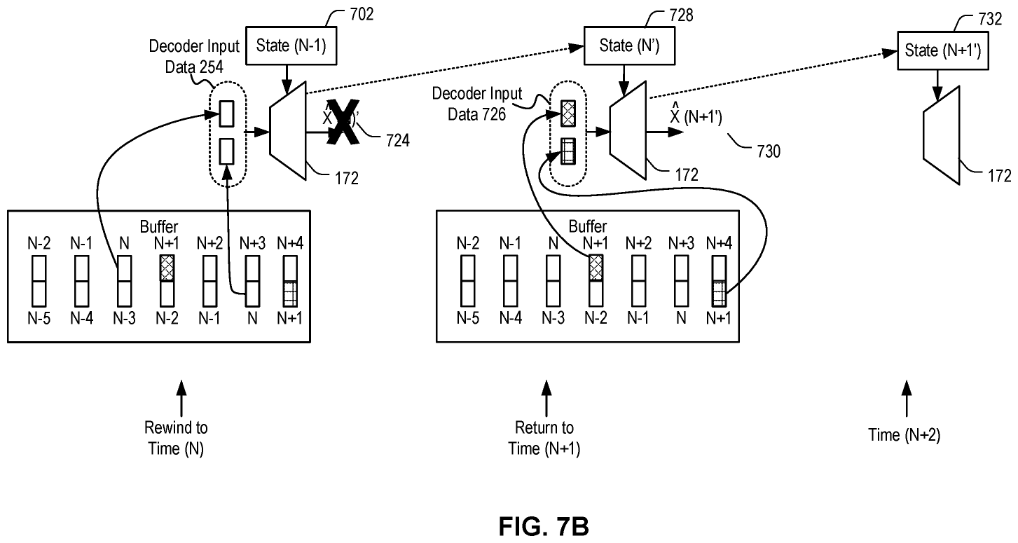

FIGS. 7A and 7B are diagrams of particular examples of further aspects of operation of a decoding device. The operations described with reference to FIGS. 7A and 7B may be performed, for example, by the receiving device 152 of FIG. 1. In FIGS. 7A and 7B, the decoder 172 uses state information based on previously performed decoding operations to improve decoding. FIG. 7A illustrates a circumstance in which a particular data frame is not available when a decoding operation is performed, and FIG. 7B illustrates rewinding and updating state data that results from the circumstances of FIG. 7A.

In FIG. 7A, at a first time (Time(N)) associated with decoding an Nth data sample, a first data frame associated with the Nth data sample is available in the buffer(s) 160, but a second data frame associated with the Nth data sample is not available. Accordingly, decoder input data 254 generated at the first time includes the first data frame (e.g., corresponding to the first encoding) and filler data 270. The decoder 172 performs decoding operations based on the decoder input data 254 and first state data 702 associated with decoding one or more prior data samples (e.g., a N−1th data sample). The decoder 172 generates output data 704 that approximates the Nth data sample and advances to decoding a next data sample (e.g., an N+1th data sample).

At a second time (Time(N+1)) associated with decoding the N+1th data sample, both data frames associated with the N+1th data sample are available in the buffer(s) 160. Additionally, in the example illustrated in FIG. 7A, the second data frame associated with the Nth data sample has arrived and is stored in the buffer(s) 160. Because a time for decoding the Nth data sample has passed, the decoding device proceeds with decoding operations associated with the N+1th data sample. For example, the decoding device generates decoder input data 706 that includes the data frames associated with the N+1th data sample. The decoder 172 performs decoding operations based on the decoder input data 706 and second state data 708 associated with decoding of one or more prior data samples (e.g., the Nth data sample) to generate output data 710 that approximates the N+1th data sample. The decoder 172 also updates the second state data 708 to generate third state data 712 for use at a third time (Time(N+2)) to perform decoding operations associated with an N+2th data sample.

Since the Nth data sample was decoded without access to all of the data frames associated with the Nth data sample, the output data 704 approximating the Nth data sample is not as accurate as it would be if all of the data frames associated with the Nth data sample had been used. For similar reasons, the second state data 708 used to decode the N+1th data sample is not as accurate as it could be, and such errors may propagate downstream to affect decoding of other data samples depending on the duration of the memory represented by the state data.

FIG. 7B illustrates operations that can be used to mitigate the effects of errors propagating in the state data. In FIG. 7B, when the second data frame associated with the Nth data sample becomes available, the decoder 172 and state data are reset (rewound) to their respective states at the first time (Time(N)), and decoding operations associated with the Nth data sample are repeated using decoder input data 254 that includes all of the data frames associated with the Nth data sample, and the first state data 702. The decoder 172 may generate output 724 based on the decoding operations, but since a time associated with decoding the Nth data sample has passed, the output 724 may be discarded. The decoder 172 also updates the second state data 708 to generate updated second state data 728, which is based on the repeated decoding operations associated with the Nth data sample. The updated second state data 728 does not include the errors that may be present in the second state data 708 since all of the data frames associated with the Nth data sample were used to generate the updated second state data 728.

In the example illustrated in FIG. 7B, the decoder 172 performs decoding operations associated with the N+1th data sample using the updated second state data 728 and the decoder input data 726 to generate output 730 representing the N+1th data sample. If the time to decode the N+1th data sample has not passed, output 730 is used to represent the N+1th data sample rather than the output 710 of FIG. 7A since the output 730 should be a more accurate representation of the N+1th data sample. However, if the time to decode the N+1th data sample has passed, the output 730 may be discarded. The decoding operations associated with the N+1th data sample also cause the third state data 712 to be updated to generate updated third state data 732, which is used while decoding an N+2th data sample.

In a particular implementation, the state data may be rewound and updated for any number of time steps, but generally errors introduced in earlier time steps have less impact on decoding operations over time, so the number of times steps rewound may have a practical limit based on a decay rate of errors in the state data. Further, in some implementations, parallel instances of the decoder 172 and state data may be used to enable decoding operations to continue while state data is updated. To illustrate, when the second data frame associated with the Nth data sample becomes available, a parallel instance of the decoder 172 may be generated (e.g., as a new processing thread), and used to generate updated state data while another instance of the decoder 172 continues to perform decoding operations associated with other data samples. In such implementations, the decoder 172 instance that is updating state data may operate faster than the decoder 172 instance that is performing decoding operations so that when the two decoder 172 instances are synchronized (e.g., at the same time step), the decoder 172 instances can be merged (e.g., the state data from the decoder 172 instance that is updating state data can be used by the other decoder 172 instance to perform decoding).

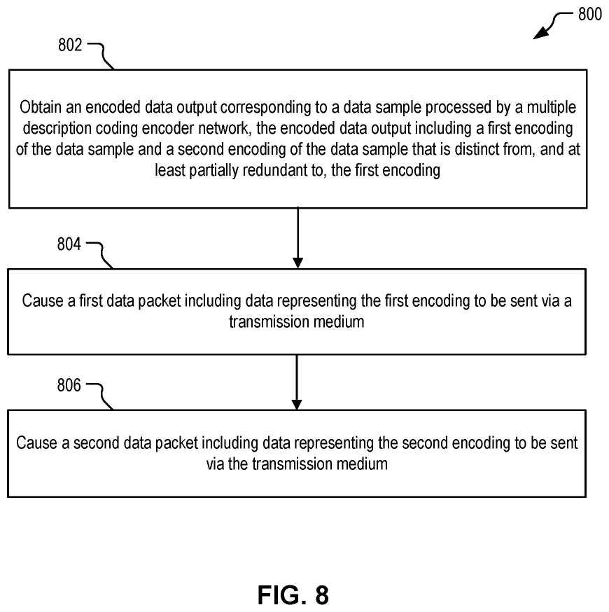

FIG. 8 is a flowchart of a particular example of a method 800 of data communication. In various implementations, the method 800 may be performed by one or more of the transmitting device 102 of FIG. 1, the encoding device 202 of any of FIGS. 2A-2D, 3A-3C, 4A-4C, the encoding device 500 of FIG. 5A or 5B, or the encoding device 600 of FIG. 6A.

In the example of FIG. 8, the method 800 includes, at block 802, obtaining an encoded data output corresponding to a data sample processed by a multiple description coding encoder network. The encoded data output includes a first encoding of the data sample and a second encoding of the data sample that is distinct from, and at least partially redundant to, the first encoding. For example, the transmitting device 102 of FIG. 1 uses the encoder 112 to generate the first encoding 120A and the second encoding 120B based on the data sample 108.

The method 800 also includes, at block 804, causing a first data packet including data representing the first encoding to be sent via a transmission medium. For example, the transmitting device 102 of FIG. 1 quantizes and packetizes the first encoding 120A in the first data packet 134A and transmits the first data packet 134A via the transmission medium 132 to the receiving device 152.

The method 800 further includes, at block 806, causing a second data packet including data representing the second encoding to be sent via the transmission medium. For example, the transmitting device 102 of FIG. 1 quantizes and packetizes the second encoding 120B in the second data packet 134B and transmits the second data packet 134B via the transmission medium 132 to the receiving device 152.

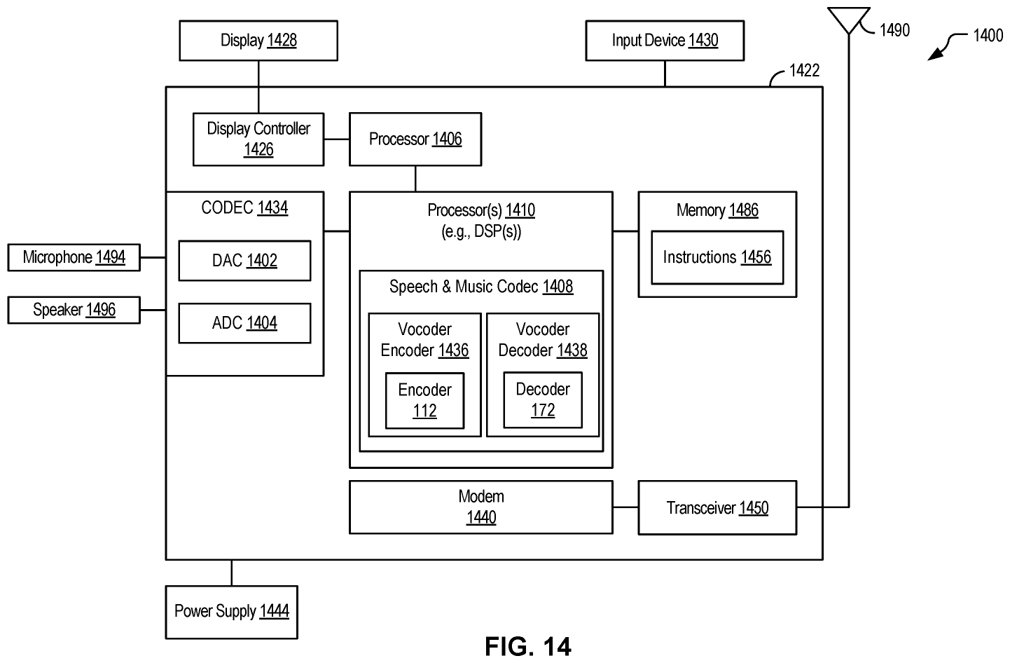

The method 800 of FIG. 8 may be implemented by a field-programmable gate array (FPGA) device, an application-specific integrated circuit (ASIC), a processing unit such as a central processing unit (CPU), a digital signal processor (DSP), a graphics processing unit (GPU), a controller, another hardware device, firmware device, or any combination thereof. As an example, the method 800 of FIG. 8 may be performed by a processor that executes instructions, such as described with reference to processor(s) 1410 of FIG. 14.

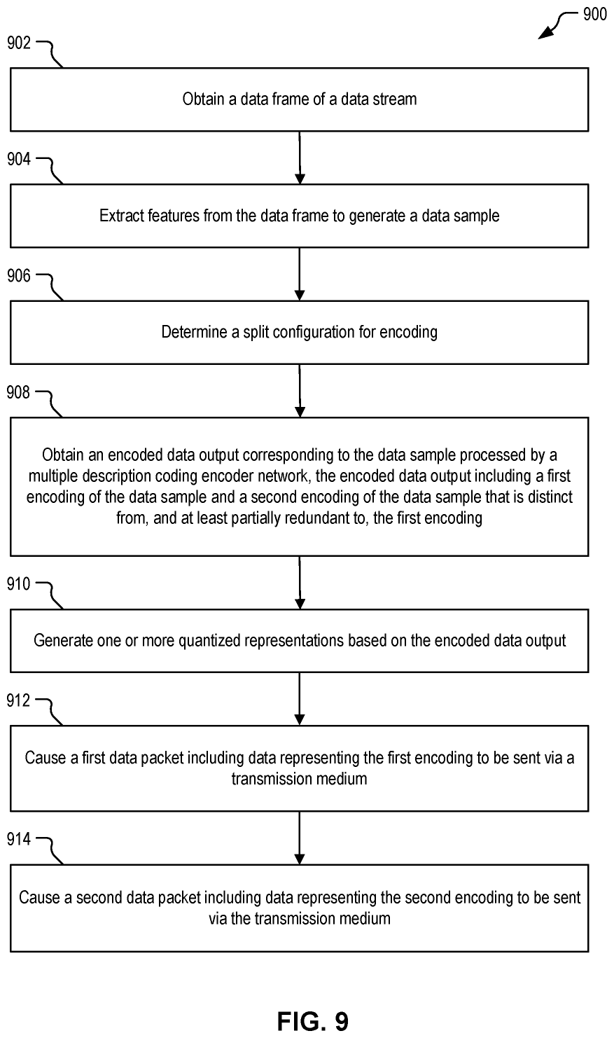

FIG. 9 is a flowchart of a particular example of a method 900 of data communication. In various implementations, the method 900 may be performed by one or more of the transmitting device 102 of FIG. 1, the encoding device 202 of any of FIGS. 2A-2D, 3A-3C, 4A-4C, the encoding device 500 of FIG. 5A or 5B, or the encoding device 600 of FIG. 6A.

In the example of FIG. 9, the method 900 includes, at block 902, obtaining a data frame of a data stream. For example, the transmitting device 102 of FIG. 1 may obtain a data frame of the data stream 104. In some implementations, the transmitting device 102 receives the data stream 104 from another device, such as a server, a user device, a microphone, a camera, etc. In other implementations, the transmitting device 102 generates the data stream 104.

In the example of FIG. 9, the method 900 includes, at block 904, extracting features from the data stream to generate a data sample. For example, the feature extractor 106 of the transmitting device 102 of FIG. 1 extracts features, such as spectrum data (e.g., cepstrum data), a pitch data, motion data, etc., to generate a data sample 108.

In the example of FIG. 9, the method 900 includes, at block 906, determining a split configuration for encoding. For example, the encoder controller 302 of FIGS. 3A-3C may determine the split configuration based on the decision metric(s) 304 and the selection criterion 306.

In the example of FIG. 9, the method 900 includes, at block 908, obtaining an encoded data output corresponding to a data sample processed by a multiple description coding encoder network. The encoded data output includes a first encoding of the data sample and a second encoding of the data sample that is distinct from, and at least partially redundant to, the first encoding. For example, the transmitting device 102 of FIG. 1 uses the encoder 112 to generate the first encoding 120A and the second encoding 120B based on the data sample 108.

In the example of FIG. 9, the method 900 includes, at block 910, generating one or more quantized representations based on the encoded data output. For example, the quantizer(s) 122 of FIG. 1 may use one or more codebooks 124 to quantize the encodings 120 to generate the quantized representations of the encoded data output (e.g., the first encoding 120A and the second encoding 120B).

The method 900 also includes, at block 912, causing a first data packet including data representing the first encoding to be sent via a transmission medium. For example, the transmitting device 102 of FIG. 1 quantizes and packetizes the first encoding 120A in the first data packet 134A and transmits the first data packet 134A via the transmission medium 132 to the receiving device 152.

The method 900 further includes, at block 914, causing a second data packet including data representing the second encoding to be sent via the transmission medium. For example, the transmitting device 102 of FIG. 1 quantizes and packetizes the second encoding 120B in the second data packet 134B and transmits the second data packet 134B via the transmission medium 132 to the receiving device 152.

The method 900 of FIG. 9 may be implemented by a FPGA device, an ASIC, a processing unit such as a CPU, a DSP, a GPU, a controller, another hardware device, firmware device, or any combination thereof. As an example, the method 900 of FIG. 9 may be performed by a processor that executes instructions, such as described with reference to processor(s) 1410 of FIG. 14.

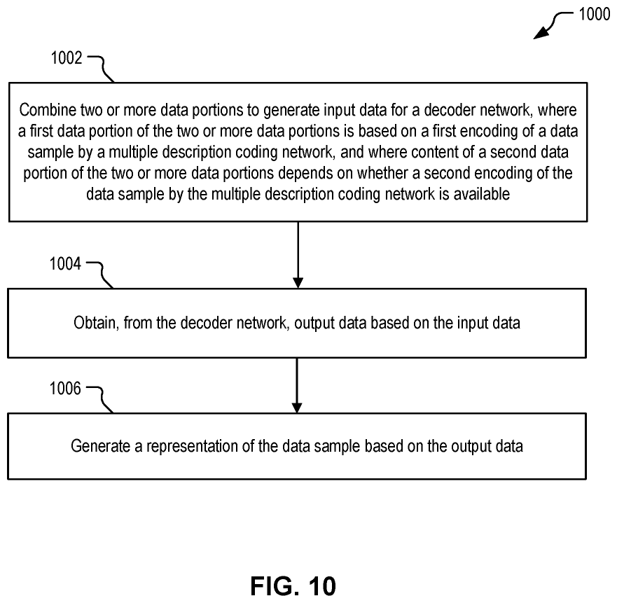

FIG. 10 is a flowchart of a particular example of a method 1000 of data communication. In various implementations, the method 1000 may be performed by one or more of the receiving device 152 of FIG. 1, the decoding device 252 of any of FIGS. 2A-2D, the decoding device 520 of FIGS. 5C-5F, or the decoding device 650 of FIG. 6B.

In the example of FIG. 10, the method 1000 includes, at block 1002, combining two or more data portions to generate input data for a decoder network. A first data portion of the two or more data portions is based on a first encoding of a data sample by a multiple description coding network, and content of a second data portion of the two or more data portions depends on whether a second encoding of the data sample by the multiple description coding network is available. For example, the decoder controller 166 of FIG. 1 may generate the input data 168 using data frames 164 from the buffer(s) 160. In this example, the input data 168 includes each data frame of the data sample that is available at a decoding time associated with the data sample. If one or more data frame of the data sample are not available at the decoding time associated with the data sample, the decoder controller 166 includes filler data in the input data 168 in place of the missing data frame(s).

The method 1000 also includes, at block 1004, obtaining, from the decoder network, output data based on the input data and, at block 1006, generating a representation of the data sample based on the output data. For example, the decoder 172 of FIG. 1 may generate output data based on the input data 168, and the output data may be stored at the buffer(s) 160 as a representation of the data sample 108.

The method 1000 of FIG. 10 may be implemented by a FPGA device, an ASIC, a processing unit such as a CPU, a DSP, a GPU, a controller, another hardware device, firmware device, or any combination thereof. As an example, the method 1000 of FIG. 10 may be performed by a processor that executes instructions, such as described with reference to processor(s) 1410 of FIG. 14.

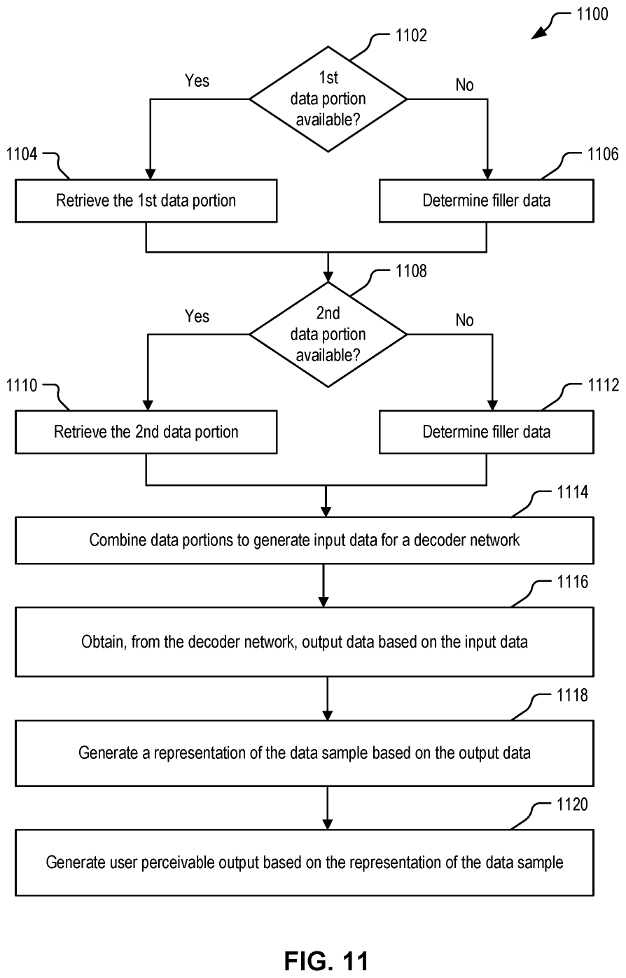

FIG. 11 is a flowchart of a particular example of a method 1100 of data communication. In various implementations, the method 1100 may be performed by one or more of the receiving device 152 of FIG. 1, the decoding device 252 of any of FIGS. 2A-2D, the decoding device 520 of FIGS. 5C-5F, or the decoding device 650 of FIG. 6B.

The method 1100 includes, at block 1102, determining whether a first data portion associated with a particular data sample is available. For example, at a decoding time associated with a data sample 108, the decoder controller 166 determines whether a first data frame is available for use as a first data portion of the input data 168.

If the first data portion is available (e.g., in the buffer(s) 160), the method 1100 includes, at block 1104, retrieving the first data portion (e.g., from the buffer(s) 160). If the first data portion is not available, the method includes, at block 1106, determining filler data for use as the first data portion. For example, if the decoder controller 166 determines that a first data frame associated with the data sample 108 to be decoded is available, the decoder controller 166 uses the first data frame as a first data portion of the input data 168. Alternatively, if the decoder controller 166 determines that the first data frame associated with the data sample 108 to be decoded is not available, the decoder controller 166 determines filler data for use as a first data portion of the input data 168. The filler data may include predetermined data or may be determined based on one or more other data frames that are available in the buffer(s) 160.

The method 1100 also includes, at block 1108, determining whether a second data portion associated with a particular data sample is available. For example, at the decoding time associated with the data sample 108, the decoder controller 166 determines whether a second data frame is available for use as a second data portion of the input data 168.

If the second data portion is available (e.g., in the buffer(s) 160), the method 1100 includes, at block 1110, retrieving the second data portion (e.g., from the buffer(s) 160). If the second data portion is not available, the method 1100 includes, at block 1112, determining filler data for use as the second data portion. For example, if the decoder controller 166 determines that a second data frame associated with the data sample 108 to be decoded is available, the decoder controller 166 uses the second data frame as a second data portion of the input data 168. Alternatively, if the decoder controller 166 determines that the second data frame associated with the data sample 108 to be decoded is not available, the decoder controller 166 determines filler data for use as a second data portion of the input data 168. The filler data may include predetermined data or may be determined based on one or more other data frames that are available in the buffer(s) 160.

In the example of FIG. 11, the method 1100 includes, at block 1114, combining data portions to generate input data for a decoder network. For example, the decoder controller 166 of FIG. 1 may generate the input data 168 using data frames 164 from the buffer(s) 160, filler data, or both. To illustrate, the input data 168 includes each data frame of the data sample 108 that is available at the decoding time associated with the data sample 108, and if one or more data frames of the data sample 108 are not available at the decoding time associated with the data sample 108, the decoder controller 166 includes filler data in the input data 168 in place of the missing data frame(s).

The method 1100 also includes, at block 1116, obtaining, from the decoder network, output data based on the input data and, at block 1118, generating a representation of the data sample based on the output data. For example, the decoder 172 of FIG. 1 may generate output data based on the input data 168, and the output data may be stored at the buffer(s) 160 as a representation of the data sample 176.

The method 1100 also includes, at block 1120, generating user perceivable output based on the representation of the data sample. For example, the renderer 178 of FIG. 1 may retrieve the representation of the data sample 176 from the buffer(s) 160 and use the representation of the data sample 176 to cause the user interface device 180 to generate user perceivable output, such as a sound, a vibration, an image, etc.

The method 1100 of FIG. 11 may be implemented by a FPGA device, an ASIC, a processing unit such as a CPU, a DSP, a GPU, a controller, another hardware device, firmware device, or any combination thereof. As an example, the method 1100 of FIG. 11 may be performed by a processor that executes instructions, such as described with reference to processor(s) 1410 of FIG. 14.

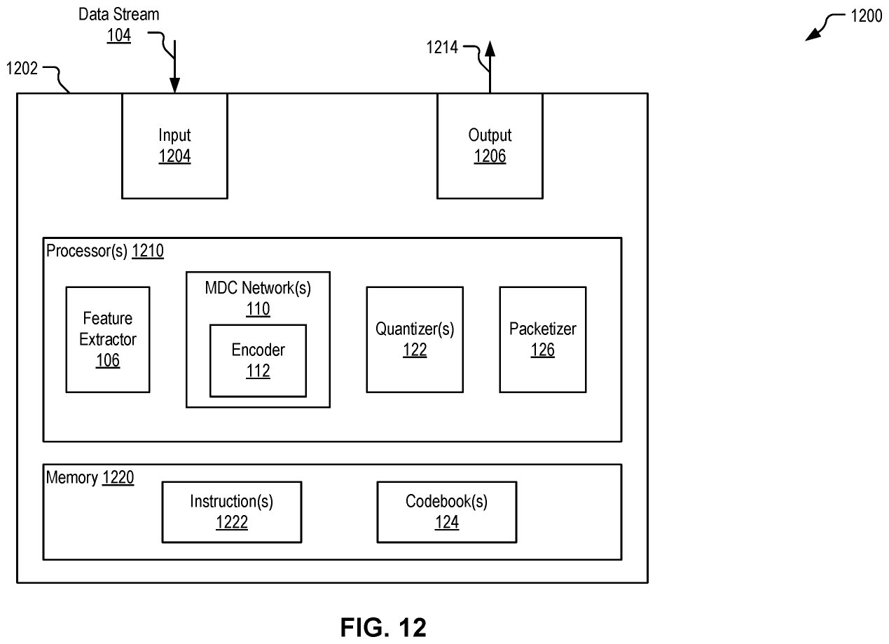

FIG. 12 depicts an implementation 1200 in which a device 1202 includes one or more processors 1210 that include components of the transmitting device 102 of FIG. 1. The device 1202 also includes an input interface 1204 (e.g., one or more bus or wireless interfaces) configured to receive input data, such as the data stream 104, and an output interface 1206 (e.g., one or more bus or wireless interfaces) configured to output data 1214, such as the encodings 120, data representing quantized encodings, data representing the data packets 134, or other data associated with the data stream 104. The device 1202 may correspond to a system-on-chip or other modular device that can be integrated into other systems to provide data encoding, such as within a mobile phone, another communication device, an entertainment system, or a vehicle, as illustrative, non-limiting examples. According to some implementations, the device 1202 may be integrated into a server, a mobile communication device, a smart phone, a cellular phone, a laptop computer, a computer, a tablet, a personal digital assistant, a display device, a television, a gaming console, a music player, a radio, a digital video player, a digital video disc (DVD) player, a tuner, a camera, a navigation device, a headset, an augmented realty headset, a mixed reality headset, a virtual reality headset, a motor vehicle such as a car, or any combination thereof.

In the illustrated implementation 1200, the device 1202 includes a memory 1220 (e.g., one or more memory devices) that includes instructions 1222 and one or more codebooks 124. The device 1202 also includes one or more processors 1210 coupled to the memory 1220 and configured to execute the instructions 1222 from the memory 1220. In this implementation 1200, the feature extractor 106, the MDC network(s) 110, the encoder 112, the quantizer(s) 122, and the packetizer 126 may correspond to or be implemented via the instructions 1222. For example, when the instructions 1222 are executed by the processor(s) 1210, the processor(s) 1210 may obtain an encoded data output corresponding to a data sample processed by a multiple description coding encoder network, where the encoded data output includes a first encoding of the data sample and a second encoding of the data sample that is distinct from, and at least partially redundant to, the first encoding. The processor(s) 1210 may also initiate transmission of a first data packet via a transmission medium, where the first data packet includes data representing the first encoding and initiate transmission of a second data packet via the transmission medium, where the second data packet includes data representing the second encoding. For example, the feature extractor 106 may generate a data sample 108 based on the data stream 104 and provide the data sample 108 as input to the encoder 112. In this example, the encoder 112 may generate two or more encodings 120 based on the data sample 108. Continuing this example, the quantizer(s) 122 may use the codebook(s) 124 to quantize the encodings 120, and the quantized encodings may be provided to the packetizer 126. The packetizer 126 generates data packets 134 based on the quantized encodings. In the implementation 1200, the processor(s) 1210 provide signals representing the data packets 134 via the output interface 1206 to one or more transmitters to initiate transmission of the data packets 134.

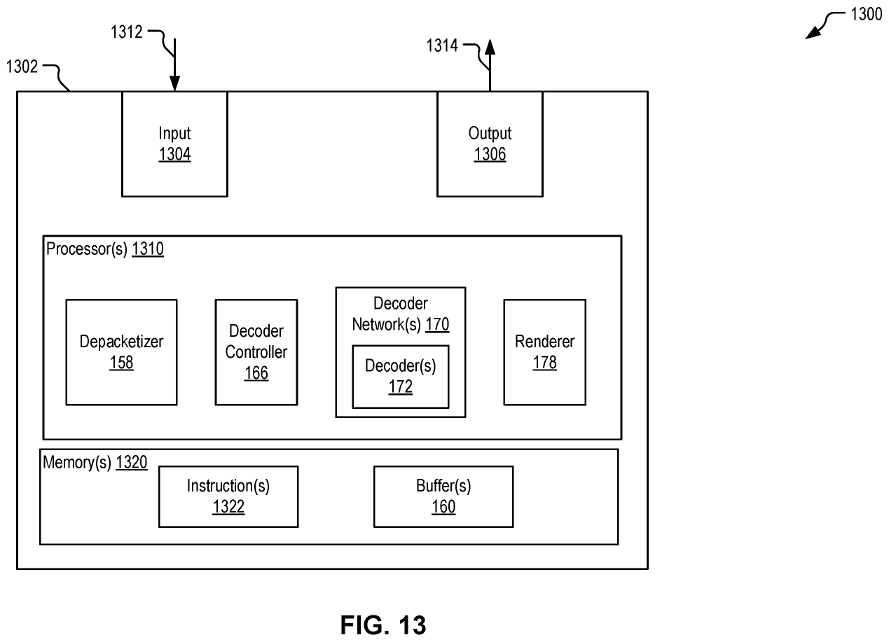

FIG. 13 depicts an implementation 1300 in which a device 1302 includes one or more processors 1310 that include components of the receiving device 152 of FIG. 1. The device 1302 also includes an input interface 1304 (e.g., one or more bus or wireless interfaces) configured to receive input data 1312, such as the data packets 134 from the receiver 154 of FIG. 1, and an output interface 1306 (e.g., one or more bus or wireless interfaces) configured to provide output 1314 based on the input data 1312, such as signals provided to the user interface device 180 of FIG. 1. The device 1302 may correspond to a system-on-chip or other modular device that can be integrated into other systems to provide data decoding, such as within a mobile phone, another communication device, an entertainment system, or a vehicle, as illustrative, non-limiting examples. According to some implementations, the device 1302 may be integrated into a server, a mobile communication device, a smart phone, a cellular phone, a laptop computer, a computer, a tablet, a personal digital assistant, a display device, a television, a gaming console, a music player, a radio, a digital video player, a DVD player, a tuner, a camera, a navigation device, a headset, an augmented realty headset, a mixed reality headset, a virtual reality headset, a motor vehicle such as a car, or any combination thereof

In the illustrated implementation 1300, the device 1302 includes a memory 1320 (e.g., one or more memory devices) that includes instructions 1322 and one or more buffers 160. The device 1302 also includes one or more processors 1310 coupled to the memory 1320 and configured to execute the instructions 1322 from the memory 1320. In this implementation 1300, the depacketizer 158, the decoder controller 166, the decoder network(s) 170, the decoder(s) 172, and/or the renderer 178 may correspond to or be implemented via the instructions 1322. For example, when the instructions 1322 are executed by the processor(s) 1310, the processor(s) 1310 may combine two or more data portions to generate input data for a decoder network, where a first data portion of the two or more data portions is based on a first encoding of a data sample by a multiple description coding network and where content of a second data portion of the two or more data portions depends on whether data based on a second encoding of the data sample by the multiple description coding network is available. The processor(s) 1310 may further obtain, from the decoder network, output data based on the input data and generate a representation of the data sample based on the output data. For example, the depacketizer 158 may strip headers from received data packets 134 and store data frames 164 extracted from a payload of each data packet 134 in the buffer(s) 160. At a decoding time associated with a particular data sample, the decoder controller 166 may generate input data 168 for a decoder 172 based on the data frames 164 associated with the particular data sample that are stored in the buffer(s) 160. To illustrate, if at least one data frame 164 associated with the particular data sample is available, the decoder controller 166 includes the available data frame 164 in the input data 168. The decoder controller 166 uses filler data to replace any data frames associated with the particular data sample that are not available. The decoder controller 166 provides the input data 168 to the decoder 172, which generates output data. The output data may be stored at the buffer(s) 160 or provided to the renderer 178 as a representation of the particular data sample.

Referring to FIG. 14, a block diagram of a particular illustrative implementation of a device is depicted and generally designated 1400. In various implementations, the device 1400 may have more or fewer components than illustrated in FIG. 14. In an illustrative implementation, the device 1400 may correspond to the transmitting device 102 of FIG. 1, the receiving device 152 of FIG. 1, or both. In an illustrative implementation, the device 1400 may perform one or more operations described with reference to FIGS. 1-13.

In a particular implementation, the device 1400 includes a processor 1406 (e.g., a CPU). The device 1400 may include one or more additional processors 1410 (e.g., one or more DSPs, one or more GPUs, or a combination thereof). The processor(s) 1410 may include a speech and music coder-decoder (CODEC) 1408. The speech and music codec 1408 may include a voice coder (“vocoder”) encoder 1436, a vocoder decoder 1438, or both. In a particular aspect, the vocoder encoder 1436 includes the encoder 112 of FIG. 1. In a particular aspect, the vocoder decoder 1438 includes the decoder 172.

The device 1400 also includes a memory 1486 and a CODEC 1434. The memory 1486 may include instructions 1456 that are executable by the one or more additional processors 1410 (or the processor 1406) to implement the functionality described with reference to the transmitting device 102 of FIG. 1, the receiving device 152 of FIG. 1, or both. The device 1400 may include a modem 1440 coupled, via a transceiver 1450, to an antenna 1490.

The device 1400 may include a display 1428 coupled to a display controller 1426. A speaker 1496 and a microphone 1494 may be coupled to the CODEC 1434. The CODEC 1434 may include a digital-to-analog converter (DAC) 1402 and an analog-to-digital converter (ADC) 1404. In a particular implementation, the CODEC 1434 may receive an analog signal from the microphone 1494, convert the analog signal to a digital signal using the analog-to-digital converter 1404, and provide the digital signal to the speech and music codec 1408 (e.g., as the data stream 104 of FIG. 1). The speech and music codec 1408 may process the digital signals. In a particular implementation, the speech and music codec 1408 may provide digital signals (e.g., output from the renderer 178 of FIG. 1) to the CODEC 1434. The CODEC 1434 may convert the digital signals to analog signals using the digital-to-analog converter 1402 and may provide the analog signals to the speaker 1496.

In a particular implementation, the device 1400 may be included in a system-in-package or system-on-chip device 1422 that corresponds to the transmitting device 102 of FIG. 1, to the encoding device 202 of FIG. 2A-D or 3A-3C, to the encoding device 600 of FIG. 6A, to the device 1202 of FIG. 12, or any combination thereof. Additionally, or alternatively, the system-in-package or system-on-chip device 1422 corresponds to the receiving device 152 of FIG. 1, to the decoding device 252 of FIGS. 2A-D, to the decoding device 520 of FIG. 5C-5F, to the decoding device 650 of FIG. 6B, to the device 1302 of FIG. 13 or any combination thereof

In a particular implementation, the memory 1486, the processor 1406, the processors 1410, the display controller 1426, the CODEC 1434, and the modem 1440 are included in the system-in-package or system-on-chip device 1422. In a particular implementation, an input device 1430 and a power supply 1444 are coupled to the system-in-package or system-on-chip device 1422. Moreover, in a particular implementation, as illustrated in FIG. 14, the display 1428, the input device 1430, the speaker 1496, the microphone 1494, the antenna 1490, and the power supply 1444 are external to the system-in-package or system-on-chip device 1422. In a particular implementation, each of the display 1428, the input device 1430, the speaker 1496, the microphone 1494, the antenna 1490, and the power supply 1444 may be coupled to a component of the system-in-package or system-on-chip device 1422, such as an interface or a controller. In some implementations, the device 1400 includes additional memory that is external to the system-in-package or system-on-chip device 1422 and coupled to the system-in-package or system-on-chip device 1422 via an interface or controller.

The device 1400 may include a smart speaker (e.g., the processor 1406 may execute the instructions 1456 to run a voice-controlled digital assistant application), a speaker bar, a mobile communication device, a smart phone, a cellular phone, a laptop computer, a computer, a tablet, a personal digital assistant, a display device, a television, a gaming console, a music player, a radio, a digital video player, a DVD player, a tuner, a camera, a navigation device, a headset, an augmented realty headset, a mixed reality headset, a virtual reality headset, a vehicle, or any combination thereof.

In conjunction with the described implementations, an apparatus includes means for combining two or more data portions to generate input data for a decoder network, where a first data portion of the two or more data portions is based on a first encoding of a data sample by a multiple description coding network and content of a second data portion of the two or more data portions depends on whether data based on a second encoding of the data sample by the multiple description coding network is available. For example, the means for combining the two or more data portions includes the decoder controller 166, the receiving device 152 of FIG. 1, the decoding device 252 of FIGS. 2A-D, the decoding device 520 of FIG. 5C-5F, the decoding device 650 of FIG. 6B, the device 1302, the processor(s) 1310 of FIG. 13, the processor 1406, the processor(s) 1410, the speech and music codec 1408, the vocoder decoder 1438 of FIG. 14, one or more other circuits or components configured to combine the two or more data portions, or any combination thereof.

The apparatus also includes means for obtaining output data based on the input data. For example, the means for obtaining the output data includes the decoder 172, the buffer(s) 160, the receiving device 152 of FIG. 1, the decoding device 252 of FIGS. 2A-D, the decoding device 520 of FIG. 5C-5F, the decoding device 650 of FIG. 6B, the device 1302, the processor(s) 1310 of FIG. 13, the processor 1406, the processor(s) 1410, the speech and music codec 1408, the vocoder decoder 1438 of FIG. 14, one or more other circuits or components configured to obtain the output data, or any combination thereof.

The apparatus also includes means for generating a representation of the data sample based on the output data. For example, the means for generating the representation of the data sample includes the decoder 172, the buffer(s) 160, the renderer 178, the user interface device 180, the receiving device 152 of FIG. 1, the decoding device 252 of FIGS. 2A-D, the decoding device 520 of FIG. 5C-5F, the decoding device 650 of FIG. 6B, the device 1302, the processor(s) 1310 of FIG. 13, the processor 1406, the processor(s) 1410, the speech and music codec 1408, the vocoder decoder 1438, the display controller 1426, the display 1428, the speaker 1496 of FIG. 14, one or more other circuits or components configured to generate the representation of the data sample, or any combination thereof.

In conjunction with the described implementations, an apparatus includes means for obtaining an encoded data output corresponding to a data sample processed by a multiple description coding encoder network, where the encoded data output includes a first encoding of the data sample and a second encoding of the data sample that is distinct from, and at least partially redundant to, the first encoding. For example, the means for obtaining the encoded data output includes the quantizer(s) 122, the packetizer 126, the modem 128, the transmitter 130, the transmitting device 102 of FIG. 1, the encoding device 202 of FIG. 2A-D or 3A-3C, the quantizer 402 of FIG. 4A, the quantizers 432, 442 of FIG. 4B, the quantizers 462, 474 of FIG. 4C, the encoding device 500 of FIGS. 5A-5B, the encoding device 600 of FIG. 6A, the device 1202 of FIG. 12, the processor 1406, the processor(s) 1410, the speech and music codec 1408, the vocoder encoder 1436 of FIG. 14, one or more other circuits or components configured to obtain the encoded data output, or any combination thereof.

The apparatus also includes means for causing a first data packet including data representing the first encoding and a second data packet including data representing the second encoding to be sent via a transmission medium. For example, the means for causing the first and second data packets to be sent via the transmission medium includes the modem 128, the transmitter 130, the transmitting device 102 of FIG. 1, the encoding device 202 of FIG. 2A-D or 3A-3C, the encoding device 500 of FIGS. 5A-5B, the encoding device 600 of FIG. 6A, the device 1202 of FIG. 12, the processor 1406, the processor(s) 1410, the modem 1440, the transceiver 1450 of FIG. 14, one or more other circuits or components configured to cause the first and second data packets to be sent via the transmission medium, or any combination thereof.

In some implementations, a non-transitory computer-readable medium includes instructions that, when executed by one or more processors of a device, cause the one or more processors to combine two or more data portions to generate input data for a decoder network, where a first data portion of the two or more data portions is based on a first encoding of a data sample by a multiple description coding network and content of a second data portion of the two or more data portions depends on whether data based on a second encoding of the data sample by the multiple description coding network is available. The instructions, when executed by the one or more processors, cause the one or more processors to obtain, from the decoder network, output data based on the input data. The instructions, when executed by the one or more processors, cause the one or more processors to generate a representation of the data sample based on the output data.

In some implementations, a non-transitory computer-readable medium includes instructions that, when executed by one or more processors of a device, cause the one or more processors to obtain an encoded data output corresponding to a data sample processed by a multiple description coding encoder network, where the encoded data output includes a first encoding of the data sample and a second encoding of the data sample that is distinct from, and at least partially redundant to, the first encoding. The instructions, when executed by the one or more processors, cause the one or more processors to initiate transmission of a first data packet via a transmission medium, where the first data packet includes data representing the first encoding and to initiate transmission of a second data packet via the transmission medium, where the second data packet includes data representing the second encoding.

Particular aspects of the disclosure are described below in sets of interrelated clauses:

According to Clause 1, a device includes: a memory; and one or more processors coupled to the memory and configured to execute instructions from the memory to: combine two or more data portions to generate input data for a decoder network, wherein a first data portion of the two or more data portions is based on a first encoding of a data sample by a multiple description coding network, and wherein content of a second data portion of the two or more data portions depends on whether data based on a second encoding of the data sample by the multiple description coding network is available; obtain, from the decoder network, output data based on the input data; and generate a representation of the data sample based on the output data.

Clause 2 includes the device of Clause 1, further including one or more user interface devices configured to generate user perceivable output based on the representation of the data sample.

Clause 3 includes the device of Clause 2, wherein the user perceivable output includes one or more of a sound, an image, or a vibration.

Clause 4 includes the device of any of Clauses 1 to 3, further including a game engine configured to modify a game state based on the representation of the data sample.

Clause 5 includes the device of any of Clauses 1 to 4, further including a jitter buffer coupled to the one or more processors, the jitter buffer configured to store data frames received from another device via a transmission medium, wherein each data frame includes data representing an encoding from the multiple description coding network.

Clause 6 includes the device of Clause 5, wherein the instructions, when executed, further cause the one or more processers to, at a processing time associated with the data sample: obtain, from the jitter buffer, a first data frame associated with the data sample; determine whether a second data frame associated with the data sample is stored in the jitter buffer; and determine the content of the second data portion of the two or more data portions based on whether the second data frame is stored in the jitter buffer.

Clause 7 includes the device of Clause 6, wherein the instructions, when executed, further cause the one or more processers to, based on a determination that the second data frame is stored in the jitter buffer, use the second data frame as the second data portion of the two or more data portions.

Clause 8 includes the device of Clause 6, wherein the instructions, when executed, further cause the one or more processers to, based on a determination that the second data frame is not stored in the jitter buffer, determine filler data, and use the filler data as the second data portion of the two or more data portions.

Clause 9 includes the device of Clause 8, wherein the filler data is determined based on a data frame associated with a different data sample.

Clause 10 includes the device of any of Clauses 1 to 9, wherein the multiple description coding encoder network is configured to generate a plurality of encodings of the data sample, the plurality of encodings including at least the first encoding and the second encoding, and wherein the plurality of encodings are distinct from one another, and at least partially redundant to one another.

Clause 11 includes the device of any of Clauses 1 to 10, wherein the instructions, when executed, further cause the one or more processers to select the decoder network from among a plurality of available decoder networks based, at least in part, on whether the data based on the second encoding of the data sample by the multiple description coding network is available.

Clause 12 includes the device of any of Clauses 1 to 11, wherein the instructions, when executed, further cause the one or more processers to, after determining that the data based on the second encoding is not available at a first time and combining the first data portion with filler data to generate the input data for the decoder network: determine, at a second time, that the data based on the second encoding has become available, the second time subsequent to the first time; and update a state of the decoder network based on the first data portion and the data based on the second encoding.

According to Clause 13, a method includes: combining two or more data portions to generate input data for a decoder network, wherein a first data portion of the two or more data portions is based on a first encoding of a data sample by a multiple description coding network, and wherein content of a second data portion of the two or more data portions depends on whether a second encoding of the data sample by the multiple description coding network is available; obtaining, from the decoder network, output data based on the input data; and generating a representation of the data sample based on the output data.

Clause 14 includes the method of Clause 13, further including generating user perceivable output based on the representation of the data sample.

Clause 15 includes the method of Clause 14, wherein the user perceivable output includes one or more of a sound, an image, or a vibration.

Clause 16 includes the method of any of Clauses 13 to 15, further including modifying a game state based on the representation of the data sample.

Clause 17 includes the method of any of Clauses 13 to 16, further including retrieving the first data portion from a jitter buffer, the jitter buffer configured to store data frames received from another device via a transmission medium, wherein each data frame includes data representing an encoding from the multiple description coding network.

Clause 18 includes the method of Clause 17, further including: determining whether a second data frame associated with the data sample is stored in the jitter buffer; and determining the content of the second data portion of the two or more data portions based on whether the second data frame is stored in the jitter buffer.

Clause 19 includes the method of Clause 18, further including, based on a determination that the second data frame is stored in the jitter buffer, using the second data frame as the second data portion of the two or more data portions.

Clause 20 includes the method of Clause 18, further including, based on a determination that the second data frame is not stored in the jitter buffer, determining filler data and using the filler data as the second data portion of the two or more data portions.

Clause 21 includes the method of Clause 20, wherein the filler data is determined based on a data frame associated with a different data sample.

Clause 22 includes the method of any of Clauses 13 to 21, wherein the multiple description coding encoder network is configured to generate a plurality of encodings of the data sample, the plurality of encodings including at least the first encoding and the second encoding, and wherein the plurality of encodings are distinct from one another, and at least partially redundant to one another.

Clause 23 includes the method of any of Clauses 13 to 22, further including selecting the decoder network from among a plurality of available decoder networks based, at least in part, on whether data based on the second encoding of the data sample by the multiple description coding network is available.

Clause 24 includes the method of any of Clauses 13 to 23, further including, after determining that data based on the second encoding is not available at a first time and combining the first data portion with filler data to generate the input data for the decoder network: determining, at a second time, that data based on the second encoding has become available, the second time subsequent to the first time; and updating a state of the decoder network based on the first data portion and the data based on the second encoding.

According to Clause 25, an apparatus includes: means for combining two or more data portions to generate input data for a decoder network, wherein a first data portion of the two or more data portions is based on a first encoding of a data sample by a multiple description coding network, and wherein content of a second data portion of the two or more data portions depends on whether a second encoding of the data sample by the multiple description coding network is available; means for obtaining, from the decoder network, output data based on the input data; and means for generating a representation of the data sample based on the output data.

Clause 26 includes the apparatus of Clause 25, further including means for generating user perceivable output based on the representation of the data sample.

Clause 27 includes the apparatus of Clause 26, wherein the user perceivable output includes one or more of a sound, an image, or a vibration.

Clause 28 includes the apparatus of any of Clauses 25 to 27, further including means for modifying a game state based on the representation of the data sample.

Clause 29 includes the apparatus of any of Clauses 25 to 28, further including means for retrieving the first data portion from a jitter buffer, the jitter buffer configured to store data frames received from another device via a transmission medium, wherein each data frame includes data representing an encoding from the multiple description coding network.

Clause 30 includes the apparatus of Clause 29, further including: means for determining whether a second data frame associated with the data sample is stored in the jitter buffer; and means for determining the content of the second data portion of the two or more data portions based on whether the second data frame is stored in the jitter buffer.

Clause 31 includes the apparatus of Clause 30, further including means for using the second data frame as the second data portion of the two or more data portions based on a determination that the second data frame is stored in the jitter buffer.

Clause 32 includes the apparatus of Clause 30, further including means for determining filler data and using the filler data as the second data portion of the two or more data portions based on a determination that the second data frame is not stored in the jitter buffer.

Clause 33 includes the apparatus of Clause 32, wherein the filler data is determined based on a data frame associated with a different data sample.

Clause 34 includes the apparatus of any of Clauses 25 to 33, wherein the multiple description coding encoder network is configured to generate a plurality of encodings of the data sample, the plurality of encodings including at least the first encoding and the second encoding, and wherein the plurality of encodings are distinct from one another, and at least partially redundant to one another.

Clause 35 includes the apparatus of any of Clauses 25 to 34, further including means for selecting the decoder network from among a plurality of available decoder networks based, at least in part, on whether data based on the second encoding of the data sample by the multiple description coding network is available.

According to Clause 36, a non-transitory computer-readable medium stores instructions executable by one or more processors to: combine two or more data portions to generate input data for a decoder network, wherein a first data portion of the two or more data portions is based on a first encoding of a data sample by a multiple description coding network, and wherein content of a second data portion of the two or more data portions depends on whether data based on a second encoding of the data sample by the multiple description coding network is available; obtain, from the decoder network, output data based on the input data; and generate a representation of the data sample based on the output data.

Clause 37 includes the non-transitory computer-readable medium of Clause 36, wherein the instructions are further executable to generate user perceivable output based on the representation of the data sample.

Clause 38 includes the non-transitory computer-readable medium of Clause 37, wherein the user perceivable output includes one or more of a sound, an image, or a vibration.

Clause 39 includes the non-transitory computer-readable medium of any of Clauses 36 to 38, wherein the instructions are further executable to modify a game state based on the representation of the data sample.

Clause 40 includes the non-transitory computer-readable medium of any of Clauses 36 to 39, wherein the instructions are further executable to: obtain, from a jitter buffer, a first data frame associated with the data sample; determine whether a second data frame associated with the data sample is stored in the jitter buffer; and determine the content of the second data portion of the two or more data portions based on whether the second data frame is stored in the jitter buffer.

Clause 41 includes the non-transitory computer-readable medium of Clause 40, wherein the instructions are further executable to, based on a determination that the second data frame is stored in the jitter buffer, use the second data frame as the second data portion of the two or more data portions.

Clause 42 includes the non-transitory computer-readable medium of Clause 40, wherein the instructions are further executable to, based on a determination that the second data frame is not stored in the jitter buffer, determine filler data, and use the filler data as the second data portion of the two or more data portions.

Clause 43 includes the non-transitory computer-readable medium of Clause 42, wherein the filler data is determined based on a data frame associated with a different data sample.

Clause 44 includes the non-transitory computer-readable medium of any of Clauses 36 to 43, wherein the multiple description coding encoder network is configured to generate a plurality of encodings of the data sample, the plurality of encodings including at least the first encoding and the second encoding, and wherein the plurality of encodings are distinct from one another, and at least partially redundant to one another.

Clause 45 includes the non-transitory computer-readable medium of any of Clauses 36 to 44, wherein the instructions are further executable to select the decoder network from among a plurality of available decoder networks based, at least in part, on whether the data based on the second encoding of the data sample by the multiple description coding network is available.

Clause 46 includes the non-transitory computer-readable medium of any of Clauses 36 to 45, wherein the instructions are further executable to, after determining that the data based on the second encoding is not available at a first time and combining the first data portion with filler data to generate the input data for the decoder network: determine, at a second time, that the data based on the second encoding has become available, the second time subsequent to the first time; and update a state of the decoder network based on the first data portion and the data based on the second encoding.

According to Clause 47, a device includes: a memory; and one or more processors coupled to the memory and configured to execute instructions from the memory to: obtain an encoded data output corresponding to a data sample processed by a multiple description coding encoder network, the encoded data output including a first encoding of the data sample and a second encoding of the data sample that is distinct from, and at least partially redundant to, the first encoding; initiate transmission of a first data packet via a transmission medium, the first data packet including data representing the first encoding; and initiate transmission of a second data packet via the transmission medium, the second data packet including data representing the second encoding.

Clause 48 includes the device of Clause 47, further including one or more microphones to capture an audio data stream including a plurality of audio data frames, wherein the data sample includes features extracted from an audio data frame of the audio data stream.

Clause 49 includes the device of Clause 47 or 48, further including one or more cameras to capture a video data stream including a plurality of image data frames, wherein the data sample includes features extracted from an image data frame of the video data stream.

Clause 50 includes the device of any of Clauses 47 to 49, further including a game engine to generate a game data stream including a plurality of game data frames, wherein the data sample includes features extracted from a game data frame of the game data stream.

Clause 51 includes the device of any of Clauses 47 to 50, further including one or more quantizers configured to generate a first quantized representation of the first encoding and a second quantized representation of the second encoding, wherein the first data packet includes the first quantized representation and the second data packet includes the second quantized representation.

Clause 52 includes the device of Clause 51, further including a first codebook and a second codebook, wherein the one or more quantizers are configured to use the first codebook to generate the first quantized representation and are configured to use the second codebook to generate the second quantized representation, wherein the first codebook is distinct from the second codebook.

Clause 53 includes the device of any of Clauses 47 to 52, further including a quantizer configured to generate a quantized representation of the encoded data output, wherein the first data packet includes a first data portion of the quantized representation and the second data packet includes a second data portion of the quantized representation.

Clause 54 includes the device of any of Clauses 47 to 53, wherein the multiple description coding encoder network is configured to generate a plurality of encodings of the data sample, the plurality of encodings including the first encoding, the second encoding, and one or more additional encodings, wherein each of the one or more additional encodings is distinct from, and at least partially redundant to, the first encoding and the second encoding.

Clause 55 includes the device of any of Clauses 47 to 54, wherein the instructions, when executed, further cause the one or more processors to determine a split configuration of the encoded data output, wherein the first encoding and the second encoding are generated based on the split configuration.

Clause 56 includes the device of Clause 55, wherein the split configuration is based on quality of the transmission medium.

Clause 57 includes the device of Clause 55 or Clause 56, wherein the split configuration is based on criticality of the data sample to output reproduction quality.

Clause 58 includes the device of any of Clauses 55 to 57, wherein the multiple description coding encoder network is configured to generate a plurality of encodings of the data sample, the plurality of encodings including the first encoding, the second encoding, and one or more additional encodings, and wherein a count of the plurality of encodings is based on the split configuration.

Clause 59 includes the device of any of Clauses 47 to 58, wherein the instructions, when executed, further cause the one or more processors to, prior to initiating transmission of the first data packet, determine a count of bits of the first data packet to be allocated to the data representing the first encoding.

Clause 60 includes the device of any of Clauses 47 to 59, wherein the multiple description coding encoder network includes an encoder portion of a feedback recurrent autoencoder.

Clause 61 includes the device of any of Clauses 47 to 60, further including one or more wireless transmitters coupled to the one or more processors and configured to transmit the first data packet and the second data packet.

According to Clause 62, a method includes: obtaining an encoded data output corresponding to a data sample processed by a multiple description coding encoder network, the encoded data output including a first encoding of the data sample and a second encoding of the data sample that is distinct from, and at least partially redundant to, the first encoding; causing a first data packet including data representing the first encoding to be sent via a transmission medium; and causing a second data packet including data representing the second encoding to be sent via the transmission medium.

Clause 63 includes the method of Clause 62, further including: obtaining an audio data frame of an audio data stream; and extracting features from the audio data frame to generate the data sample.

Clause 64 includes the method of any of Clauses 62 to 63, further including: obtaining an image data frame of a video data stream; and extracting features of the image data frame to generate the data sample.

Clause 65 includes the method of any of Clauses 62 to 64, further including: obtaining a game data frame of a game data stream; and extracting features of the game data frame to generate the data sample.

Clause 66 includes the method of any of Clauses 62 to 65, further including: generating a first quantized representation of the first encoding, wherein the first data packet includes the first quantized representation; and generating a second quantized representation of the second encoding, wherein the second data packet includes the second quantized representation.

Clause 67 includes the method of Clause 66, wherein a first codebook is used to generate the first quantized representation and a second codebook is used to generate the second quantized representation, wherein the first codebook is distinct from the second codebook.

Clause 68 includes the method of any of Clauses 62 to 67, further including generating a quantized representation of the encoded data output, wherein the first data packet includes a first data portion of the quantized representation and the second data packet includes a second data portion of the quantized representation.

Clause 69 includes the method of any of Clauses 62 to 68, further including generating one or more additional encodings of the data sample, wherein each of the one or more additional encodings is distinct from, and at least partially redundant to, the first encoding and the second encoding.

Clause 70 includes the method of any of Clauses 62 to 69, further including determining a split configuration of the encoded data output, wherein the first encoding and the second encoding are generated based on the split configuration.

Clause 71 includes the method of Clause 70, wherein the split configuration is based on quality of the transmission medium.

Clause 72 includes the method of Clause 70 or Clause 71, wherein the split configuration is based on criticality of the data sample to output reproduction quality.

Clause 73 includes the method of any of Clauses 70 to 72, wherein the multiple description coding encoder network encodes a plurality of encodings based on the data sample, the plurality of encodings including the first encoding, the second encoding, and one or more additional encodings, and wherein a count of the plurality of encodings is based on the split configuration.

Clause 74 includes the method of any of Clauses 62 to 73, further including, prior to initiating transmission of the first data packet, determining a count of bits of the first data packet to be allocated to the data representing the first encoding.

Clause 75 includes the method of any of Clauses 62 to 74, wherein the multiple description coding encoder network includes an encoder portion of a feedback recurrent autoencoder.

According to Clause 76, an apparatus includes: means for obtaining an encoded data output corresponding to a data sample processed by a multiple description coding encoder network, the encoded data output including a first encoding of the data sample and a second encoding of the data sample that is distinct from, and at least partially redundant to, the first encoding; means for initiating transmission of a first data packet via a transmission medium, the first data packet including data representing the first encoding; and means for initiating transmission of a second data packet via the transmission medium, the second data packet including data representing the second encoding.

Clause 77 includes the apparatus of Clause 76, further including means for capturing an audio data stream including a plurality of audio data frames, wherein the data sample includes features extracted from an audio data frame of the audio data stream.

Clause 78 includes the apparatus of any of Clauses 76 to 77, further including means for capturing a video data stream including a plurality of image data frames, wherein the data sample includes features extracted from an image data frame of the video data stream.

Clause 79 includes the apparatus of any of Clauses 76 to 78, further including means for generating a game data stream including a plurality of game data frames, wherein the data sample includes features extracted from a game data frame of the game data stream.

Clause 80 includes the apparatus of any of Clauses 76 to 79, further including means for generating a first quantized representation of the first encoding and a second quantized representation of the second encoding, wherein the first data packet includes the first quantized representation and the second data packet includes the second quantized representation.

Clause 81 includes the apparatus of any of Clauses 76 to 80, further including means for generating a quantized representation of the encoded data output, wherein the first data packet includes a first data portion of the quantized representation and the second data packet includes a second data portion of the quantized representation.

Clause 82 includes the apparatus of any of Clauses 76 to 81, wherein the multiple description coding encoder network is configured to generate a plurality of encodings of the data sample, the plurality of encodings including the first encoding, the second encoding, and one or more additional encodings, wherein each of the one or more additional encodings is distinct from, and at least partially redundant to, the first encoding and the second encoding.

Clause 83 includes the apparatus of any of Clauses 76 to 82, further including means for determining a split configuration of the encoded data output, wherein the first encoding and the second encoding are generated based on the split configuration.

Clause 84 includes the apparatus of Clause 83, wherein the split configuration is based on quality of the transmission medium.

Clause 85 includes the apparatus of Clause 83 or Clause 84, wherein the split configuration is based on criticality of the data sample to output reproduction quality.

Clause 86 includes the apparatus of any of Clauses 83 to 85, wherein the multiple description coding encoder network is configured to generate a plurality of encodings of the data sample, the plurality of encodings including the first encoding, the second encoding, and one or more additional encodings, and wherein a count of the plurality of encodings is based on the split configuration.

Clause 87 includes the apparatus of any of Clauses 76 to 86, further including means for determining a count of bits of the first data packet to be allocated to the data representing the first encoding.

Clause 88 includes the apparatus of any of Clauses 76 to 87, wherein the multiple description coding encoder network includes an encoder portion of a feedback recurrent autoencoder.

Clause 89 includes the apparatus of any of Clauses 76 to 88, means for transmitting the first data packet and the second data packet.

According to Clause 90, a non-transitory computer-readable medium stores instructions executable by one or more processors to: obtain an encoded data output corresponding to a data sample processed by a multiple description coding encoder network, the encoded data output including a first encoding of the data sample and a second encoding of the data sample that is distinct from, and at least partially redundant to, the first encoding; initiate transmission of a first data packet via a transmission medium, the first data packet including data representing the first encoding; and initiate transmission of a second data packet via the transmission medium, the second data packet including data representing the second encoding.

Clause 91 includes the non-transitory computer-readable medium of Clause 90, wherein the instructions are further executable to obtain an audio data stream including a plurality of audio data frames, wherein the data sample includes features extracted from an audio data frame of the audio data stream.

Clause 92 includes the non-transitory computer-readable medium of any of Clauses 90 to 91, wherein the instructions are further executable to obtain a video data stream including a plurality of image data frames, wherein the data sample includes features extracted from an image data frame of the video data stream.

Clause 93 includes the non-transitory computer-readable medium of any of Clauses 90 to 92, wherein the instructions are further executable to generate a game data stream including a plurality of game data frames, wherein the data sample includes features extracted from a game data frame of the game data stream.

Clause 94 includes the non-transitory computer-readable medium of any of Clauses 90 to 93, wherein the instructions are further executable to generate a first quantized representation of the first encoding and a second quantized representation of the second encoding, wherein the first data packet includes the first quantized representation and the second data packet includes the second quantized representation.

Clause 95 includes the non-transitory computer-readable medium of any of Clauses 90 to 94, wherein the instructions are further executable to generate a quantized representation of the encoded data output, wherein the first data packet includes a first data portion of the quantized representation and the second data packet includes a second data portion of the quantized representation.

Clause 96 includes the non-transitory computer-readable medium of any of Clauses 90 to 95, wherein the multiple description coding encoder network is configured to generate a plurality of encodings of the data sample, the plurality of encodings including the first encoding, the second encoding, and one or more additional encodings, wherein each of the one or more additional encodings is distinct from, and at least partially redundant to, the first encoding and the second encoding.

Clause 97 includes the non-transitory computer-readable medium of any of Clauses 90 to 96, wherein the instructions are further executable to determine a split configuration of the encoded data output, wherein the first encoding and the second encoding are generated based on the split configuration.

Clause 98 includes the non-transitory computer-readable medium of Clause 97, wherein the split configuration is based on quality of the transmission medium.

Clause 99 includes the non-transitory computer-readable medium of Clause 97 or Clause 98, wherein the split configuration is based on criticality of the data sample to output reproduction quality.

Clause 100 includes the non-transitory computer-readable medium of any of Clauses 97 to 99, wherein the multiple description coding encoder network is configured to generate a plurality of encodings of the data sample, the plurality of encodings including the first encoding, the second encoding, and one or more additional encodings, and wherein a count of the plurality of encodings is based on the split configuration.

Clause 101 includes the non-transitory computer-readable medium of any of Clauses 90 to 100, wherein the instructions are further executable to determine a count of bits of the first data packet to be allocated to the data representing the first encoding.

Clause 102 includes the non-transitory computer-readable medium of any of Clauses 90 to 101, wherein the multiple description coding encoder network includes an encoder portion of a feedback recurrent autoencoder.

Those of skill would further appreciate that the various illustrative logical blocks, configurations, modules, circuits, and algorithm steps described in connection with the implementations disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, such implementation decisions are not to be interpreted as causing a departure from the scope of the present disclosure.

The steps of a method or algorithm described in connection with the implementations disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor may read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed implementations is provided to enable a person skilled in the art to make or use the disclosed implementations. Various modifications to these implementations will be readily apparent to those skilled in the art, and the principles defined herein may be applied to other implementations without departing from the scope of the disclosure. Thus, the present disclosure is not intended to be limited to the implementations shown herein and is to be accorded the widest scope possible consistent with the principles and novel features as defined by the following claims.

What is claimed is:

1. A device comprising:
a memory; and
one or more processors coupled to the memory and configured to execute instructions from the memory to:
combine two or more data portions to generate input data for a decoder network, wherein a first data portion of the two or more data portions is based on a first encoding of a data sample by a multiple description coding network, and wherein content of a second data portion of the two or more data portions depends on whether data based on a second encoding of the data sample by the multiple description coding network is available;
obtain, from the decoder network, output data based on the input data; and
generate a representation of the data sample based on the output data.

2. The device of claim 1, further comprising one or more user interface devices configured to generate user perceivable output based on the representation of the data sample.

3. The device of claim 2, wherein the user perceivable output includes one or more of a sound, an image, or a vibration.

4. The device of claim 1, further comprising a game engine configured to modify a game state based on the representation of the data sample.

5. The device of claim 1, further comprising a jitter buffer coupled to the one or more processors, the jitter buffer configured to store data frames received from another device via a transmission medium, wherein each data frame includes data representing an encoding from the multiple description coding network.

6. A method comprising:
combining two or more data portions to generate input data for a decoder network, wherein a first data portion of the two or more data portions is based on a first encoding of a data sample by a multiple description coding network, and wherein content of a second data portion of the two or more data portions depends on whether a second encoding of the data sample by the multiple description coding network is available;
obtaining, from the decoder network, output data based on the input data; and
generating a representation of the data sample based on the output data.

7. The method of claim 6, further comprising retrieving the first data portion from a jitter buffer, the jitter buffer configured to store data frames received from another device via a transmission medium, wherein each data frame includes data representing an encoding from the multiple description coding network.

8. The method of claim 7, further comprising:
determining whether a second data frame associated with the data sample is stored in the jitter buffer; and
determining the content of the second data portion of the two or more data portions based on whether the second data frame is stored in the jitter buffer.

9. The method of claim 8, further comprising, based on a determination that the second data frame is stored in the jitter buffer, using the second data frame as the second data portion of the two or more data portions.

10. The method of claim 8, further comprising, based on a determination that the second data frame is not stored in the jitter buffer, determining filler data and using the filler data as the second data portion of the two or more data portions.

11. The method of claim 6, further comprising selecting the decoder network from among a plurality of available decoder networks based, at least in part, on whether data based on the second encoding of the data sample by the multiple description coding network is available.

12. The method of claim 6, further comprising, after determining that data based on the second encoding is not available at a first time and combining the first data portion with filler data to generate the input data for the decoder network:
determining, at a second time, that data based on the second encoding has become available, the second time subsequent to the first time; and
updating a state of the decoder network based on the first data portion and the data based on the second encoding.

13. A device comprising:
a memory; and
one or more processors coupled to the memory and configured to execute instructions from the memory to:
obtain an encoded data output corresponding to a data sample processed by a multiple description coding encoder network, the encoded data output including a first encoding of the data sample and a second encoding of the data sample that is distinct from, and at least partially redundant to, the first encoding;
initiate transmission of a first data packet via a transmission medium, the first data packet including data representing the first encoding; and
initiate transmission of a second data packet via the transmission medium, the second data packet including data representing the second encoding.

14. The device of claim 13, further comprising one or more microphones to capture an audio data stream including a plurality of audio data frames, wherein the data sample includes features extracted from an audio data frame of the audio data stream.

15. The device of claim 13, further comprising one or more cameras to capture a video data stream including a plurality of image data frames, wherein the data sample includes features extracted from an image data frame of the video data stream.

16. The device of claim 13, further comprising a game engine to generate a game data stream including a plurality of game data frames, wherein the data sample includes features extracted from a game data frame of the game data stream.

17. The device of claim 13, further comprising one or more quantizers configured to generate a first quantized representation of the first encoding and a second quantized representation of the second encoding, wherein the first data packet includes the first quantized representation and the second data packet includes the second quantized representation.

18. The device of claim 13, further comprising a quantizer configured to generate a quantized representation of the encoded data output, wherein the first data packet includes a first data portion of the quantized representation and the second data packet includes a second data portion of the quantized representation.

19. The device of claim 13, wherein the multiple description coding encoder network is configured to generate a plurality of encodings of the data sample, the plurality of encodings including the first encoding, the second encoding, and one or more additional encodings, wherein each of the one or more additional encodings is distinct from, and at least partially redundant to, the first encoding and the second encoding.

20. The device of claim 13, wherein the instructions, when executed, further cause the one or more processors to determine a split configuration of the encoded data output, wherein the first encoding and the second encoding are generated based on the split configuration.

21. The device of claim 20, wherein the split configuration is based on quality of the transmission medium.

22. The device of claim 20, wherein the split configuration is based on criticality of the data sample to output reproduction quality.

23. The device of claim 20, wherein the multiple description coding encoder network is configured to generate a plurality of encodings of the data sample, the plurality of encodings including the first encoding, the second encoding, and one or more additional encodings, and wherein a count of the plurality of encodings is based on the split configuration.

24. The device of claim 13, wherein the instructions, when executed, further cause the one or more processors to, prior to initiating transmission of the first data packet, determine a count of bits of the first data packet to be allocated to the data representing the first encoding.

25. The device of claim 13, wherein the multiple description coding encoder network comprises an encoder portion of a feedback recurrent autoencoder.

26. The device of claim 13, further comprising one or more wireless transmitters coupled to the one or more processors and configured to transmit the first data packet and the second data packet.

27. A method comprising:
obtaining an encoded data output corresponding to a data sample processed by a multiple description coding encoder network, the encoded data output including a first encoding of the data sample and a second encoding of the data sample that is distinct from, and at least partially redundant to, the first encoding;
causing a first data packet including data representing the first encoding to be sent via a transmission medium; and
causing a second data packet including data representing the second encoding to be sent via the transmission medium.

28. The method of claim 27, further comprising generating one or more additional encodings of the data sample, wherein each of the one or more additional encodings is distinct from, and at least partially redundant to, the first encoding and the second encoding.

29. The method of claim 27, further comprising determining a split configuration of the encoded data output, wherein the first encoding and the second encoding are generated based on the split configuration.

30. The method of claim 27, further comprising, prior to initiating transmission of the first data packet, determining a count of bits of the first data packet to be allocated to the data representing the first encoding.
